(19) United States
(12) Patent Application Publication
(10) Pub. No.: US 2021/0005520 A1
(43) Pub. Date: Jan. 7, 2021

(54) METHOD AND APPARATUS FOR MANUFACTURING ARRAY DEVICE

(71) Applicant: SHARP KABUSHIKI KAISHA, Sakai City (JP)

(72) Inventors: TOSHIYA ISHIO, Sakai City (JP); HITOSHI AOKI, Sakai City (JP)

(21) Appl. No.: 16/917,810

(22) Filed: Jun. 30, 2020

Related U.S. Application Data
(60) Provisional application No. 62/869,727, filed on Jul. 2, 2019.

(51) Int. Cl. H01L 21/66; H01L 23/00; H01L 21/67

(52) U.S. Cl. CPC H01L 22/20; H01L 24/799; H01L 21/67288; H01L 24/98

(57) ABSTRACT

A method for manufacturing an array device includes a placing step of providing a plurality of elements in an array on a first surface of a substrate, an element separating step of separating a plurality of element chips from one another so that each element chip includes one or more elements, an inspecting step of inspecting the plurality of elements, a removing step of removing any element chip of the plurality of element chips from the surface of the substrate on the basis of a result of the inspecting step, and a mounting step of, after the removing step, mounting an element of at least the elements other than an element of the element chip thus removed onto a mounting substrate by transfer from the substrate, the mounting substrate being different from the substrate.

### DESCRIPTION

### Technical Field

The present invention relates to a method and an apparatus for manufacturing an array device.

### Background Art

Examples of use of elements arranged like a grid include display devices, lighting devices, sensing devices, and the like. The term “display devices” encompasses monochromatic or color devices that display character information, images, and the like, and the term “lighting devices” encompasses devices, such as LED lights, laser lights (surface-emitting lasers of which are capable of arraying), floodlight projectors, and headlights, that emit visible light, ultraviolet light, or infrared light. Arraying allows a lighting device to have an increased radiation intensity. The term “sensing devices” encompasses photosensitive sensors that senses light ranging from ultraviolet light to infrared light, including visible light, temperature sensors such as thermopiles, and the like. Arraying allows a sensing device to sense a light or heat distribution or the like. As such array devices, display devices for use in televisions, monitors, and the like need to be especially high in yield.

As can be seen in a liquid crystal display, for example, in a case where LEDs are used as a direct backlight, a display device is mounted with LED chips (or LED packages) determined to be conforming items and arrayed one by one at substantially equal spacings in a matrix on a mounting substrate by using a die bonding apparatus or the like.

In recent years, LED displays have attracted attention because of their display brightness. Such a display device, too, is mounted with LED chips (or packaged packages) obtained in a dicing step and arrayed one by one in a matrix by using mounting equipment. Such a one-by-one mounting method is called “pick-and-place scheme”. The pick-and-place scheme allows mounting of LED chips (or packages) determined to be conforming items in an inspecting step, and therefore makes it possible to manufacture display devices at a comparatively high yield rate.

However, in order for LED chips (or packages) to be arrayed and mounted at equal spacings, this scheme needs approximately 720 LED chips and approximately 480 LED chips (in the case of color, three times as many LED chips) to be loaded breadthwise and lengthwise, respectively, even for SD image quality, and in the case of color, the number of LED chips that are loaded is as very large as approximately 1.04 million, so that loading speed needs to be emphasized. However, even high-speed mounting equipment capable of 200000/h loading needs five hours or longer, and in that case, the LED chips need to be placed at spacings of approximately 100 micrometers. Such display devices are suitable for large-sized screens, and a drawback of such display devices is that they are hardly made higher in definition as small-sized display devices to be loaded, especially, into AR (augmented reality) or VR (virtual reality) glasses or the like. As for lighting devices, too, there are lighting devices each having a plurality of light-emitting elements arrayed to give a predetermined brightness; however, as in the case of display devices, the pick-and-place scheme is unsuitable to reduction of size of these lighting devices, and these lighting devices need arraying for reduction of size.

### CITATION LIST

### Patent Literature

[PTL 1] Japanese Unexamined Patent Application Publication No. 2005-284305 (published on Oct. 13, 2005)

### SUMMARY OF INVENTION

### Technical Problem

Under the circumstances, a method for mounting LEDs or the like in an array state is conceivable. In the case of an array device having LED elements mounted in an array state, an array obtained in an LED element forming step can be used as-is; therefore, for example, the LED elements can be easily placed at spacings of 5 micrometers or narrower. However, since the LED elements are in an array state, the presence of even one defective LED element impairs the quality of a display device, resulting in a defective product. To address this problem by improving the yields of display devices, PTL 1 discloses a repair technology with which to load a conforming LED package onto an LED package having a defective LED element sealed therein with resin.

However, a wire on a mounting substrate that is connected to a defective LED package needs to be cut off, and an LED package having replaced a defective LED package is higher than other LED packages, so that a protective layer or the like needs to be formed for a uniform surface finish. This results in a very complicated repair process. This method can also be diverted to a lighting device that is obtained with a plurality of light-emitting element chips in an area state, but similarly results in a complicated repair process. Thus, array devices such as display devices are poor in yield to provide high-quality array devices, and undesirably complicate a repair for improving yields.

The present invention has as an object to provide a manufacturing method that can be easily executed for high yields of array devices and a manufacturing apparatus for use in the manufacture.

### Solution to Problem

(1) In an aspect of the present invention, there is provided a method for manufacturing an array device, the method including: a placing step of providing a plurality of elements in an array on a first surface of a substrate; an element separating step of separating a plurality of element chips from one another so that each element chip includes one or more elements; an inspecting step of inspecting the plurality of elements; a removing step of removing any element chip of the plurality of element chips from the surface of the substrate on the basis of a result of the inspecting step; and a mounting step of, after the removing step, mounting an element of at least the elements other than an element of the element chip thus removed onto a mounting substrate by transfer from the substrate, the mounting substrate being different from the substrate.

(2) Further, an embodiment of the present invention may be directed to the method according to the configuration (1) described above, further including a loading step of, after the removing step, loading an element chip of a desired quality onto the substrate on the basis of the result of the inspecting step.

(3) Further, an embodiment of the present invention may be directed to the method according to the configuration (1) described above, wherein the mounting step includes mounting each element chip onto the mounting substrate while maintaining relative coordinates of the plurality of elements.

(4) Further, an embodiment of the present invention may be directed to the method according to the configuration (1) described above, wherein the elements are light-emitting elements.

(5) Further, an embodiment of the present invention may be directed to the method according to the configuration (1) described above, wherein the mounting substrate is an LSI substrate.

(6) Further, an embodiment of the present invention may be directed to the method according to the configuration (1) described above, wherein the substrate is a translucent substrate that transmits light.

(7) Further, an embodiment of the present invention may be directed to the method according to the configurations (1) and (6) described above, wherein the removing step includes weakening bonding power between an element chip and the translucent substrate by selectively irradiating the element chip with light falling on a surface of the translucent substrate opposite to the surface on which the elements are provided.

(8) Further, an embodiment of the present invention may be directed to the method according to the configuration (1) described above, wherein the mounting step includes performing mounting with reference to a determination result as to whether electrical continuity has been achieved by bringing electrodes of the element chips and electrodes of the mounting substrate into contact with each other.

(9) Further, an embodiment of the present invention may be directed to the method according to the configuration (1) described above, further including a post-mounting inspecting step of, after the mounting step, determining whether an element chip that has been mounted is defective.

(10) Further, an embodiment of the present invention may be directed to the method according to the configurations (1) and (9) described above, further including a post-mounting removing step of removing, with reference to an inspection result yielded in the post-mounting inspecting step, a defective element chip that has been mounted and a remounting step of, after the post-mounting removing step, mounting an element chip of a desired quality onto the mounting substrate with a paste material containing conductive particles.

(11) Further, an embodiment of the present invention may be directed to the method according to the configuration (1) described above, further including a substrate removing step of removing the substrate after the mounting step.

(12) Further, an embodiment of the present invention may be directed to the method according to the configurations (1) and (11) described above, wherein the substrate removing step after the mounting step includes removing the substrate and selectively removing a defective element chip on the basis of a result of a post-mounting inspecting step.

(13) Further, an embodiment of the present invention may be directed to the method according to the configurations (1) and (2) described above, wherein the removing step includes removing a defective element chip from the substrate by attaching the defective element chip to a second substrate that is different from the substrate, and the loading step includes an attaching step of further attaching an element chip of a desired quality onto the defective element chip attached to the second substrate and a transferring step of transferring the element chip of the desired quality attached to the second substrate onto the substrate on the basis of positional information of the defective element chip removed from the substrate and thereby replacing the defective element chip thus removed with the element chip of the desired quality.

(14) Further, an embodiment of the present invention may be directed to the method according to the configurations (1), (9), and (10) described above, wherein the remounting step includes an attaching step of attaching an element chip of a desired quality onto a defective element chip removed from the mounting substrate by using the substrate or a third substrate that is different from the substrate and a transferring step of transferring the element chip of the desired quality attached to the substrate or the third substrate onto the mounting substrate on the basis of positional information of the defective element chip removed from the mounting substrate and thereby replacing the defective element chip thus removed with the element chip of the desired quality.

(15) Further, in an aspect of the present invention, there is provided an apparatus for manufacturing an array device, the apparatus including: a determination section that determines, on the basis of an inspection result of each element, whether an element chip separated so as to include one or a plurality elements is removed; and a selective irradiation section that, on the basis of a determination result yielded by the determination section, selectively irradiates the element chip with light falling a second surface of a translucent substrate opposite to a first surface of the translucent substrate on which the element chip is placed.

(16) Further, an embodiment of the present invention may be directed to the apparatus according to the configuration (15) described above, further including a selective removal section that removes a particular element chip from the translucent substrate.

(17) Further, an embodiment of the present invention may be directed to the apparatus according to the configuration (15) described above, further including an inspection section that inspects the plurality of elements.

(18) Further, an embodiment of the present invention may be directed to the apparatus according to the configuration (15) described above, further including a loading section that loads a different element chip in a place on the translucent substrate from which the element chip was removed.

### Advantageous Effects of Invention

An aspect of the present invention achieves a method and an apparatus for manufacturing an array device that make it possible to manufacture high yields of array devices in a simple way.

### BRIEF DESCRIPTION OF DRAWINGS

FIG. 1 is a diagram explaining a method for manufacturing an array device according to Embodiment 1 of the present invention.

FIG. 2 illustrates (a) a cross-sectional view and (b) a plan view showing a configuration of an array device that is obtained by the manufacturing method of the present invention.

FIG. 3 is a plan view of an example of an array device that is obtained by the manufacturing method of the present invention.

FIG. 4 illustrates (a) a cross-sectional view and (b) a plan view showing a configuration of a modification of an array device that is obtained by the manufacturing method of the present invention.

FIG. 5 is an enlarged view of a portion A of (a) of FIG. 2.

FIG. 6 is an enlarged view of a portion B of (a) of FIG. 4.

FIG. 7 is a diagram explaining a method for manufacturing an array device according to Embodiment 2 of the present invention.

FIG. 8 is a diagram explaining a method for manufacturing an array device according to Embodiment 3 of the present invention.

FIG. 9 is a diagram explaining a method for manufacturing an array device according to Embodiment 4 of the present invention.

FIG. 10 is a diagram explaining a method for manufacturing an array device according to Embodiment 5 of the present invention.

FIG. 11 is a diagram explaining a method for manufacturing an array device according to Embodiment 6 of the present invention.

FIG. 12 is a diagram explaining a method for manufacturing an array device according to a modification of Embodiment 6 of the present invention.

FIG. 13 is an enlarged view of a portion D of FIG. 11 and a portion E of FIG. 12.

FIG. 14 is an explanatory diagram of an arrayed element region and a replacement element region.

FIG. 15 is a diagram explaining a method for an array device according to a modification of Embodiment 1 of the present invention.

FIG. 16 is a diagram explaining a method for an array device according to a modification of Embodiment 2 of the present invention.

FIG. 17 is a diagram explaining a method for an array device according to a modification of Embodiment 3 of the present invention.

FIG. 18 is a diagram explaining a method for an array device according to a modification of Embodiment 4 of the present invention.

FIG. 19 is a flow chart showing steps of manufacturing an array device according to Embodiment 1 of the present invention.

FIG. 20 is a flow chart showing steps of manufacturing an array device according to the modification of Embodiment 1 of the present invention.

FIG. 21 is a flow chart showing steps of manufacturing an array device according to Embodiment 3 of the present invention.

FIG. 22 is a flow chart showing steps of manufacturing an array device according to the modification of Embodiment 3 of the present invention.

FIG. 23 is a flow chart showing steps of manufacturing an array device according to Embodiment 4 of the present invention.

FIG. 24 is a flow chart showing steps of manufacturing an array device according to the modification of Embodiment 4 of the present invention.

FIG. 25 is a flow chart showing steps of manufacturing an array device according to Embodiment 5 of the present invention.

FIG. 26 is a flow chart showing steps of manufacturing an array device according to Embodiment 6 of the present invention.

FIG. 27 is a flow chart showing steps of manufacturing an array device according to the modification of Embodiment 6 of the present invention.

FIG. 28 is a diagram for providing a brief overview of an apparatus (repair apparatus) for manufacturing an array device according to the present invention.

FIG. 29 is a block diagram showing a configuration of the apparatus (repair apparatus) for manufacturing an array device according to the present invention.

### DESCRIPTION OF EMBODIMENTS

### Embodiment 1

Embodiments of the present invention are described in detail below.

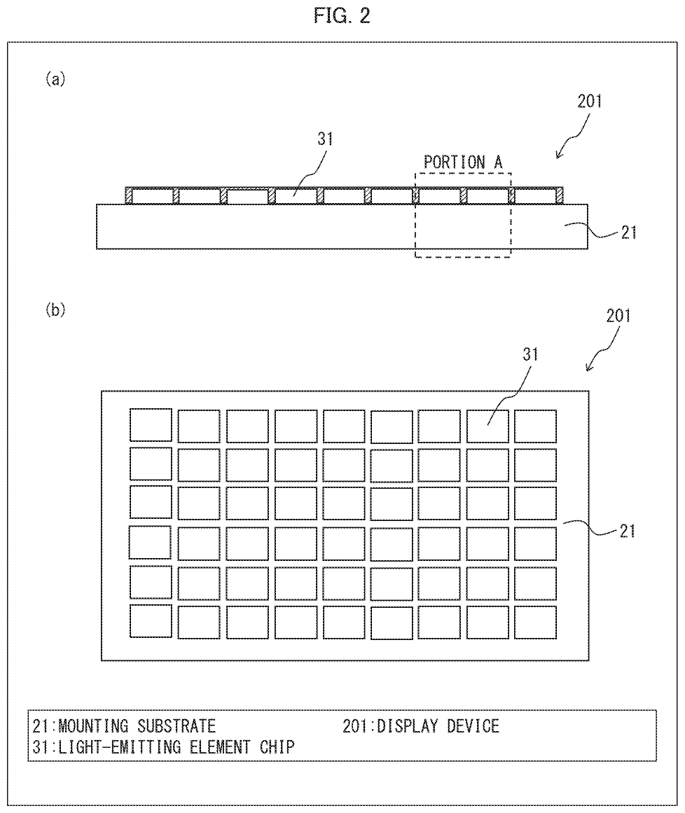

First, an array device that is obtained by a manufacturing method or apparatus of the present invention is described. (a) of FIG. 2 is a cross-sectional view of an array device (display device) 201 that is obtained by the manufacturing method or apparatus of the present invention, and (b) of FIG. 2 is a plan view of the array device 201. As shown in (a) and (b) of FIG. 2, a plurality of light-emitting element chips 31 each including one light-emitting element as an element are mounted in a matrix on a mounting substrate 21. All light-emitting element chips 31 loaded into array devices manufactured by the manufacturing method or apparatus of the present invention are conforming chips (furthermore, using only light-emitting element chips 31 of a desired rank brings about further improvement in quality). A reason for this is that a replacing step including a removing step and, furthermore, a loading step is executed on the basis of an inspection result obtained in an inspecting step by associating positional information of each element with a result of a conforming item or a defective item as to whether it lights or fails to light. Furthermore, not only are elements classified into the two ranks, namely lighting and failure to light, but also conforming elements are classified into a plurality of ranks according to characteristics such as luminance, wavelength, forward voltage Vf, and on the basis of the classification (i.e. a result of the inspecting step), elements that are comparatively close in characteristics such as luminance, wavelength, forward voltage Vf to one another are loaded, whereby improved display quality is attained with a reduction of defects attributed to luminance unevenness or color unevenness. Instead of being arrayed in a matrix, the elements may be in a staggered arrangement or a honeycomb array, provided they function as an array device. As for a plurality of light-emitting elements that are obtained in an array state, light-emitting element chips have their light-emitting elements separated from one another so that a defective light-emitting element (or a light-emitting element of a rank other than the desired rank) can be removed and replaced by a conforming light-emitting element (or a light-emitting element of the desired rank), and in a state where the array state are substantially maintained, only conforming light-emitting elements are obtained by being transferred onto an LSI substrate (LSI wafer or LSI chip) serving as the mounting substrate. Since the mounting substrate is an LSI substrate including at least one of a drive circuit, a control circuit, and the like, the element chips are stacked on the LSI substrate of the drive circuit, the control circuit, or the like, which has conventionally been provided around the mounting substrate. This is favorable to reduction of size. As the light-emitting elements, LEDs or surface-emitting lasers can be used, and in the present structure, blue LEDs are used. LEDs and lasers can be used as a lighting device such as an LED light, a laser light, a floodlight projector, or a headlight or as a monochromatic display device. Blue light will do as-is; however, white light may be emitted by providing yellow light-emitting phosphors on the light-emitting elements, such as blue LEDs or blue lasers. Further, by being each provided separately with a red, blue, or green color filter, the light-emitting elements function as a lighting device capable of color lighting or as a color display device. An alternative method for obtaining three colors, namely red, green, and blue, involves the use of light-emitting elements obtained by providing a red light-emitting phosphor or a green light-emitting phosphor separately on each of light-emitting elements such as blue LEDs or lasers and light-emitting elements provided with no phosphors. In this case, too, a color filter may be combined. Further, in a case where ultraviolet, blue-violet, or violet light-emitting elements are further used, red, green, and blue light-emitting phosphors need only be provided separately on each of the light-emitting elements. In this case, too, it is possible to further provide a color filter. Providing a display device with a color filter reduces the amount of light that can be transmitted. This makes the display device darker than in a case where no color filter is used, but brings about improvement in color reproducibility. A phosphor film provided with a thickness of, for example, 10 micrometers or thicker brings about improvement in color reproducibility even without a color filter. Further, a phosphor film whose binder is obtained by dispersing phosphor particles in a transparent resin is easily fixable onto an element. Further, using a quantum dot phosphor instead of a phosphor brings about further improvement in color reproducibility. A monochromatic display device will do; however, a color display device can be obtained by a proper combination of phosphors or quantum dot phosphors of each color, color filters of each color, and the like.

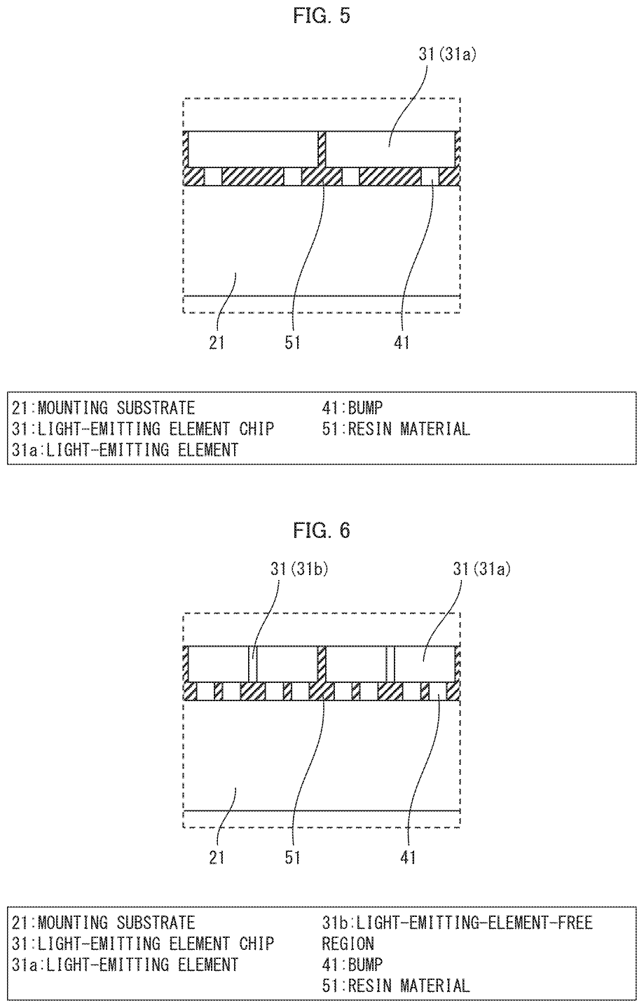

FIG. 5 is an enlarged view of a cross-section of a portion A of FIG. 2, and an LSI substrate serving as the mounting substrate 21 is electrically connected to each light-emitting element chip 31 via bumps 41. A bump material needs only be determined as appropriate according to the temperature at which the bump material is connected and the sizes of electrodes of the light-emitting element chip 31 and the mounting substrate 21. In this example, gold bumps, which have high connection reliability, are used, formed on the LSI substrate side by a plating method, and subjected to gold-to-gold bonding. Alternatively, copper, nickel, tin, lead, solder, indium, an alloy thereof, or the like can be used. Although gold, copper, nickel, and the like have high melting points and need a bonding temperature of 300° C. or higher, using nanoparticles thereof allows bonding at a bonding temperature of approximately 150° C. to 250° C. The term “nanoparticles” here refers to particles of the order of nanometers. Even in a case where nanoparticles are used in the after-mentioned remounting step, a temperature in the remounting step exerts almost no influence, as a state close to a post-mounting bulk has been reached after bonding through the use of nanoparticles in a mounting step.

Alternatively, a bump can also be formed by a printing method, a dispensing method, an inkjet method, or the like instead of being formed by the plating method. For example, the dispensing method, the printing method, and the plating method or the inkjet method are arranged in this descending order according to electrode size, and at a threshold of approximately 10 micrometers or less, the plating method or the inkjet method is favorable. Further, in the case of a connection between a bump and an electrode or between bumps, they can be electrically connected to each other through a resin material, called “ACF (anisotropic conductive film)” or “ACP (anisotropic conductive paste)”, that has conductive particles dispersed therein or via an NCF (nonconductive film) or an NCP (nonconductive paste) that has no conductive particles dispersed therein. Using the ACF, ACP, NCF, or NCP makes it possible to attain a lower bonding temperature than bonding of metal bulks such as gold-to-gold bonding. For example, assuming that the thermal curing temperature of a resin that is used in the ACF, ACP, NCF, or NCP is set, for example, at 200° C., it is possible to change from the bonding temperature of 300° C. or higher of gold-to-gold bonding to 200° C. Furthermore, using a UV-curable resin can further lower the curing temperature. Further, using a thermoplastic resin makes it easy to replace element chips. The ACF or ACP needs conductive particles to be trapped between the bump and the electrode or between the bumps, and the NCF or NCP needs the bump and the electrode or the bumps to be connected to each other. As for spacings between element chips, since light-emitting element chips having their respective elements separated from one another in a state of substantially maintaining relative coordinates of elements in an array state that are obtained by a semiconductor wafer process are mounted by transfer, processing can be easily performed when the elements are placed at spacings of 5 micrometers or narrower. This is favorable to obtaining a small-sized array device. In the present structure, the light-emitting elements are placed at narrower spacings of 2 micrometers, and the light-emitting element chips have a size of 10 micrometers on a side. When the size of one light-emitting element chip is 10 micrometers and spacings between elements are 2 micrometers, 1000 pixels (in a case where 1000 light-emitting element chips are monochromatically arranged) measure 12 millimeters on a side. The pick-and-place scheme, under which elements to serve as pixels are loaded one by one in a chip state or a package state, takes time for manufacturing and causes the light-emitting element chips to be placed at spacings of 10 micrometers, which is much larger than 5 micrometers. In this case, 1000 pixels measure approximately 110 millimeters on a side. Therefore, the separation of the pixels from one another makes a non-light-emitting portion other than the pixels conspicuous in terms of display quality, resulting in 9 times as large a size. For example, this makes loading into AR glasses difficult. As the light-emitting element chips become smaller in size, the size difference becomes wider. For example, when the size of a light-emitting element chip is 5 micrometers and spacings between elements are 2 micrometers, 2000 pixels measure approximately 14 millimeters on a side. However, the pick-and-place scheme results in approximately 210 millimeters, ending up with 18 times as large a difference.

Between the light-emitting element chips and between the light-emitting element chips and the mounting substrate, a silicone-based black resin is used that has an effect of reducing transmission of light and that deteriorates less under light. As this black resin, an underfill material may be commonly used, or the aforementioned ACF, ACP, NCF, or NCP may be used. This resin serves to improve connection reliability by firmly fixing each light-emitting element chip 31 to the mounting substrate 21 and avoid a crosstalk, i.e. a mixture of lights from the light-emitting element chips. In the presence of a step that involves the use of a high-energy laser beam such as far-ultraviolet rays with each light-emitting element chip 31 mounted on the mounting substrate 21, this resin has an effect of avoiding damage to the mounting substrate 21. It is preferable that the resin be black to avoid a crosstalk; however, even if the resin has a different color, the resin has an effect of avoiding transmission of light, although the resin is not as effective as it is when it is black. Further, the resin has an effect of improving connection reliability through firm fixing and an effect of avoiding damage to the mounting substrate 21 caused by a laser beam.

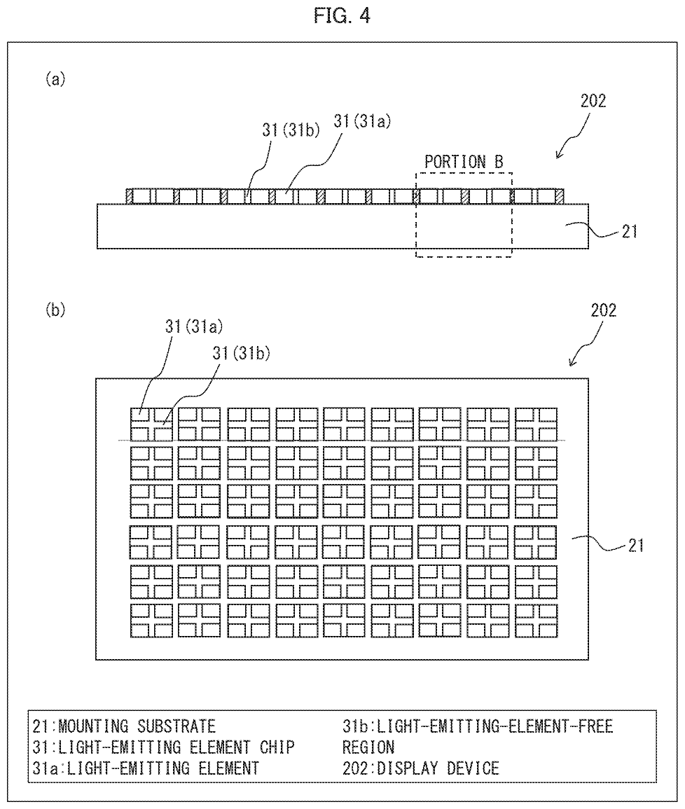

FIG. 4 is a diagram showing a case where light-emitting element chips serving as the light-emitting element chips 31 each include a plurality of light-emitting elements 31a with a light-emitting-element-free region 31b provided therebetween (in the array device of FIG. 2 or 4, the light-emitting-element-free region 31b can also be used as a place in which to form grooves by which the elements are separated from one another). In this example, the light-emitting element chips 31 each include four light-emitting elements 31a; however, there is no limit on the number. Depending on facilities, handling of element chips at the time of manufacture may be difficult, and chip sizes can be enlarged to sizes that can be handled. For example, in a case where a common die-bonding suction collet is used, the applicable minimum size is approximately 150 micrometers per side; therefore, in the case of light-emitting elements each measuring 10 micrometers per side, a light-emitting element chip may include 15×15 of these light-emitting elements as one chip. When the collet is not a single-hole collet but a multiple-hole collet with as small hole diameters as possible, smaller chips can be easily handled, as even the small holes can give suction force. Furthermore, using a pressure-sensitive adhesive jig or substrate makes it possible to handle smaller light-emitting element chips.

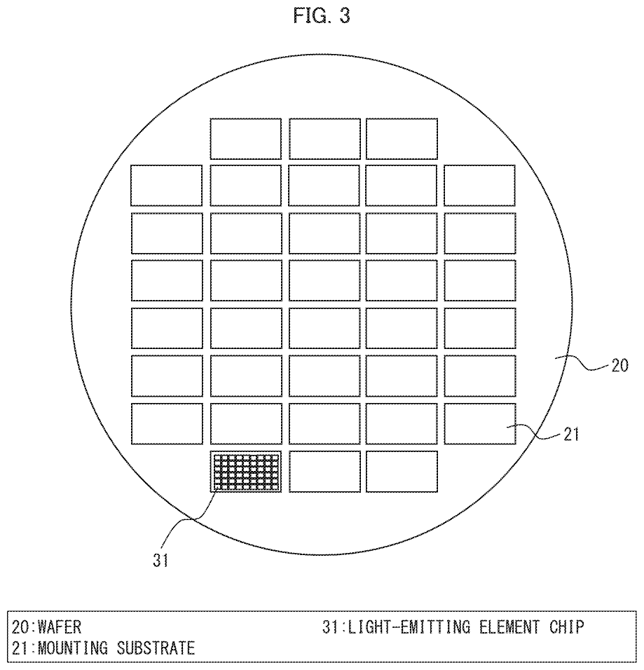

(a) of FIG. 4 is a cross-sectional view of an array device (display device) 202, and (b) a plan view. FIG. 6 is an enlarged view of a portion B of FIG. 4, and the light-emitting element chips 31 are mounted over the mounting substrate 21 via the bumps 41. The configuration is the same as that of FIG. 2 except that the light-emitting element chips 31 each include a plurality of light-emitting elements 31a. Although the following manufacturing method or apparatus is described on the basis of a single array device 201 or 202 (display device), units of array devices 201 or 202 (display devices) may be manufactured, and that way is superior in mass-producibility. Further, the mounting substrate 21 may be an LSI including a drive circuit, a control circuit, or the like of each light-emitting element 31a (display element), and that way makes it unnecessary to provide a separate drive circuit around the display device. This is a lot more favorable as it makes reduction of size possible for loading into a small-sized portable device. FIG. 3 shows an example of a case where mounting substrates 21 are LSIs, and the mounting substrates 21 may be manufactured as a wafer unit of LSIs and the light-emitting elements 31a may be manufactured as a display device unit. Furthermore, mounting a plurality of display device units onto an LSI wafer is superior in mass-producibility. Furthermore, there is a method for manufacturing light-emitting elements 31a (display elements) in the same size as an LSI wafer, and that way brings about improvement in production speed and is therefore superior in mass-producibility. Meanwhile, in a case where the substrate is remarkably warped or other cases, the degree of difficulty of manufacture may be lowered by separately manufacturing ½ sizes, ⅓ sizes, ¼ sizes, or other sizes of a display device. An array device of the present invention can be obtained by a manufacturing step or apparatus that makes it possible to maintain an array state through a step of transferring as many element chips as possible at once, separate elements from one another so that an element of a rank other than the desired rank (such as one that fails to light) can be removed, and remove the element at a stage prior to the mounting step.

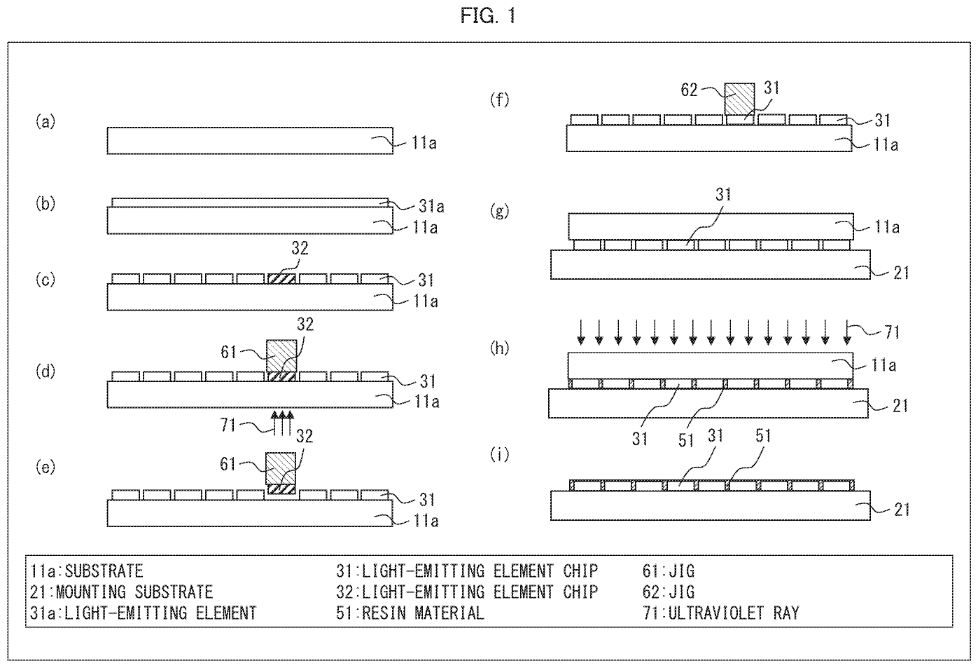

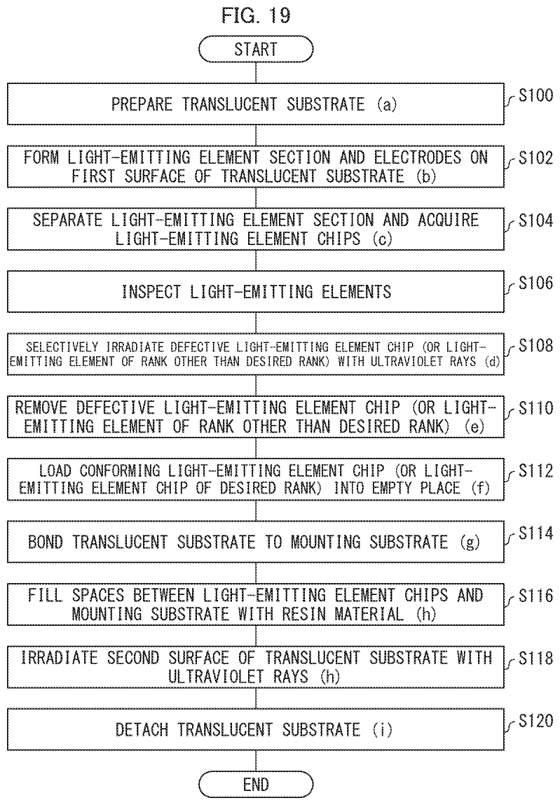

Next, a method for manufacturing an array device according to Embodiment 1 is described with reference to FIGS. 1 and 19. FIG. 1 is a diagram explaining the method for manufacturing an array device according to Embodiment 1, and FIG. 19 is a flow chart showing steps of manufacturing an array device according to Embodiment 1. Embodiment 1 describes a case where an array device is manufactured on an LSI substrate.

A method for manufacturing an array device according to an embodiment includes a placing step of providing a plurality of elements in an array on a first surface of a substrate, an element separating step of separating a plurality of element chips from one another on the substrate so that each element chip includes one or more elements, an inspecting step of inspecting the plurality of elements, a removing step of removing any element chip of the plurality of element chips from the surface of the substrate on the basis of a result of the inspecting step, and a mounting step of, after the removing step, mounting an element of at least the elements other than an element of the element chip thus removed onto a mounting substrate by transfer from the substrate, the mounting substrate being different from the substrate. Note here that the “placing step” may include both a case of “forming an array device on a substrate” and a case of “forming an array device and then placing it on a substrate”. In the following, steps of the method for manufacturing an array device according to the present embodiment are described in detail.

In Embodiment 1 to a modification of Embodiment 6 below, the term “conforming light-emitting chip” refers to a light-emitting element chip of the desired rank, and the term “defective light-emitting element chip” refers to a light-emitting element chip of a rank other than the desired rank.

(Step S100)

First, in step S100, as shown in (a) of FIG. 1, a sapphire substrate is prepared as a translucent substrate 11a.

(Step S102)

Next, in step S102, a plurality of elements are provided in an array on a first surface of the translucent substrate 11a (sapphire substrate). For example, elements 31a are formed on the first surface of the translucent substrate 11a. The elements 31a may for example be LED elements of a type of light-emitting element.

First, as shown in (b) of FIG. 1, a desired film is subjected to crystal growth on the first surface of the translucent substrate 11a (sapphire substrate), and photolithography or the like is used to form a plurality of light-emitting elements 31a provided in an array and electrodes (including bumps) electrically connected to the light-emitting elements 31a.

(Step S104)

In step S104, the translucent substrate 11a (sapphire substrate) is separated into a plurality of light-emitting element chips 31 so that each element chip includes one or more elements. For example, as shown in (b) and (c) of FIG. 1, the light-emitting element chips 31 are obtained by separating the light-emitting elements 31a formed on the translucent substrate 11a (sapphire substrate) into units of single or multiple light-emitting elements 31a. In so doing, the separation can be made by dicing a region free of the light-emitting elements 31a with a dicing blade or a laser or by performing dry etching. The present example employs a dry etching method, which makes it easy to form light-emitting element chips at narrow spacings.

(Step S106)

In step S106, the plurality of elements are inspected. The inspecting step may take place after step S102 or step S104.

The inspecting step includes causing the light-emitting elements 31 emit light and measuring and recording the intensity, wavelength, and the like of the light. Furthermore, a point (forward voltage (Vf)) at which a current value abruptly rises in response to an applied voltage is measured and recorded. Specifications are drawn up in advance separately for use in each of types, models, or the like of product, and on the basis of measurement data, elements falling within a desired range of specifications (rank) are used in a display device. The term “rank” here means, for example, a degree regarding whether quality is high or low. For example, elements of a rank that is higher than a predetermined rank refer to elements of a quality that is higher than a predetermined quality. In so doing, a light-emitting element chip of a rank other than the desired rank is removed on the basis of mapping data obtained by mapping for each of the positions of the light-emitting elements 31a. In so doing, two ranks, namely conforming items and defective items, may be set up; however, it is more preferable that only light-emitting elements 31a (display elements) that are close in performance to one another be assembled to manufacture one array device 201 or 202 (display device) according to the intensity and wavelength of light and, furthermore, the forward voltage (Vf), as doing so reduces luminance unevenness and color unevenness of the array device 201 or 202 (display device) and therefore makes it possible to manufacture a display device of higher quality.

(Steps S108 and S110)

In steps S108 and S110, a defective light-emitting chip is selectively irradiated with ultraviolet rays, and on the basis of a result of the inspecting step, any element chip of the plurality of element chips is removed from the surface of the substrate. For example, as shown in (d) and (e) of FIG. 1, on the basis of the result of the inspecting step, a light-emitting element chip 32 of a rank other than the desired rank (such as one that fails to light) is removed from the substrate 11a. For example, a suction jig 61 that sticks by negative pressure of air is pressed against the light-emitting element chip 32. In that state, the element chip is selectively irradiated with light falling on a surface of the translucent substrate opposite to the surface on which the elements are provided, whereby the bonding power between the element chip and the translucent substrate is weakened. For example, a region in which the light-emitting element chip 32 of a rank other than the desired rank is located is selectively irradiated with light of a wavelength of 20 to 400 nm in an ultraviolet range falling on the surface of the translucent substrate 11a (sapphire substrate) opposite to the surface on which the light-emitting element chip 32 is placed. In the case of a light-emitting elements 31a that is a gallium nitride element, irradiation with a pulse laser of nearly 250 nm causes gallium nitride nearly up to a level of several tens of nanometers from the translucent substrate 11a (sapphire substrate) to be decomposed into gallium and nitrogen, so that the light-emitting element 31a can be removed from the translucent substrate 11a (sapphire substrate).

In a case where a laser beam needs to be confined to a narrow range, such as a case where the light-emitting element chip 32 is small, only a particular area masked with a nontransparent material that does not transmit light needs only be irradiated, and the light-emitting element chip 32 is removed with the suction jig 61. In so doing, such relationships are set to hold that the translucent substrate 11a (sapphire substrate) is greater than the suction jig 61 in terms of bonding power with respect to light-emitting element chips 31 of the desired rank and the suction jig is greater than the translucent substrate 11a (sapphire substrate) in terms of bonding power with respect to the light-emitting element chip 32 of a rank other than the desired rank.

(Step S112)

Next, in step S112, after the removing step, an element chip of the desired rank is loaded onto the substrate on the basis of the result of the inspecting step. Note here that the case where an element chip of the desired quality is loaded on the basis of the result of the inspecting step encompasses a case where an element chip of the desired quality is mounted indirectly on the basis of the result of the inspecting step, such as a case where the position of the element chip thus removed (empty place) is recognized with a camera, a sensor, or the like and an element chip of the desired quality is mounted. For example, as shown in (f) of FIG. 1, the suction jig 61, which was used to remove the light-emitting element chip 32, is used again or a different suction jig 62 is used to load a light-emitting element chip 31 of the desired rank by alignment into the empty place on the first surface of the translucent substrate 11a (sapphire substrate) from which the light-emitting element chip 32 of a rank out of the desired range of ranks, such as one that fails to light, was removed earlier. In so doing, not all light-emitting element chips are loaded, but a light-emitting element chip is loaded only into a portion from which the light-emitting element chip 32 of a rank other than the desired rank was removed. For this reason, mounting equipment having a 200000/h level that emphasizes loading speed has difficulty in loading this light-emitting element chip, as the mounting equipment has a loading accuracy of approximately ± several tens of micrometers. Alternatively, mounting equipment that emphasizes accuracy with ±1 micrometer or less may be used, although it needs a certain amount of loading speed. Using such mounting equipment involves replacing only a light-emitting element chip of a rank other than the desired rank instead of loading all element chips under the pick-and-place scheme, thus needing only an incomparably small total amount of loading time for one array device. This makes it possible to load light-emitting element chips even at narrow spacings of, for example, 2 micrometers.

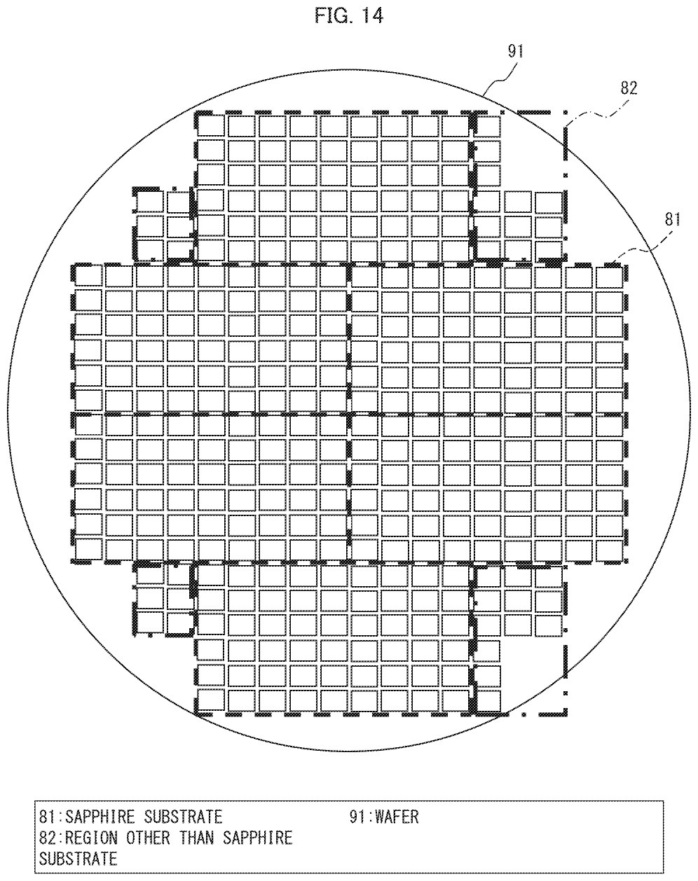

As the light-emitting element chip 31 for use in this loading step, a light-emitting element chip 31 of the desired rank in the inspecting step may be used from a region 82 other than a display device region 81 of a translucent substrate 11a (sapphire substrate) (sapphire substrate in the form of a wafer 91), which is a translucent substrate, as shown in FIG. 14.

In so doing, a manufacturing apparatus is used that makes it possible to remove the light-emitting element chips 32 of specifications other than the desired specifications, such as one that fails to light, by, on the basis of an inspection result (including positional information) of each light-emitting element 31a, pressing the suction jig 61 against the light-emitting element chip 32 provided on the first surface of the translucent substrate 11a (sapphire substrate), which is a translucent substrate, and by selectively irradiating the light-emitting element chips 32 with a laser beam falling on the surface of the translucent substrate 11a (sapphire substrate) opposite to the surface on which the elements and the chips are placed. Furthermore, it is advisable that selective irradiation with light can be performed on the basis of the inspection result by masking with a mask having an opening, as doing so makes it easy to pinpoint-irradiate only the light-emitting element chip 32 to be removed with light. For example, in a case where the light-emitting element chip 32 includes a plurality of elements (light-emitting elements) 31a, the light-emitting element chip 32 is determined to be of a rank other than the desired rank if even one light-emitting element a is of a rank other than the desired rank (including a similar rank), e.g. if one light-emitting element 31a fails to light. This is an example of how a determination is made on the basis of rules set up in advance for each type or model of array device.

The inspecting step has been described here as a separate step; however, if the manufacturing apparatus includes a storage section that acquires and records an inspection result, one manufacturing apparatus can be achieved. This makes it possible to reduce conveyance time and stoppage time.

By thus using the sapphire substrate, which is the translucent substrate 11a, as the substrate, only light-emitting element chips 31 of the desired rank (which may include a similar rank or may include a plurality of ranks) are loaded on the translucent substrate 11a (sapphire substrate) after the step of loading light-emitting element chips.

In loading a light-emitting element chip 31 onto the sapphire substrate, which is a translucent substrate, as the substrate, a material having adhesive properties is used as an adhesion layer of the light-emitting element chip 31. Temporary bonding needs only be done here, and transfer from the sapphire substrate, subjected to temporary bonding, to the mounting substrate can be done by using properties of the material such as photo-curability, thermal plasticity, water solubility, and vaporizability. Examples of photo-curable materials include visible light curing materials and ultraviolet curable materials. A generally well-known ultraviolet curable resin is cured with ultraviolet rays at a wavelength of 200 to 400 nm. Acrylic resin, which is generally well known, is widely used as an adhesive material for a dicing sheet, and is also used in a so-called UV sheet. The UV sheet includes a base material and a pressure-sensitive adhesive material applied to the base material, exhibits strong adhesiveness at the time of dicing when a wafer or a substrate is pasted and divided into individual pieces, and exhibits lower pressure-sensitive adhesiveness due to curing of the adhesive material by irradiation with ultraviolet rays before the small pieces are picked up after the division. This is how an ultraviolet curable resin is used. In recent years, there has been developed a resin that is cured with visible light (at a wavelength of approximately 400 to 800 nm). At 400 nm or longer, the material is characterized by having an increased light transmission. There are epoxy resin, polyimide resin, and the like in addition to acrylic resin. Using these materials makes it possible to perform temporary bonding to the sapphire substrate serving as the translucent substrate 11a and again remove the sapphire substrate serving as the translucent substrate 11a. A thermoplastic resin softens at or above a glass transition temperature or a melting point, and hardens at or below the temperature. Adhesion can be achieved by utilizing the properties of such a resin. This type of resin is used in a so-called hotmelt adhesive agent. There are a variety of materials examples of which include a polyimide material, a styrene-butadiene rubber material, and the like. Polyimide resin, which has a glass transition temperature of around 200° C. to 400° C., can achieve adhesion by being cooled after being once heated to 400° or higher at or above the glass transition temperature. Reheating to 400° C. or higher makes detachment possible. Examples of water-soluble materials include carbohydrate materials, protein materials, and the like usable examples of which include starch, collagen, gelatin, and the like. These materials need only be detached by moisture, and turning the moisture into hot water or vapor by heating makes detachment easy. Examples of organic materials include materials that can be detached by being decomposed, and instantaneously heating and vaporizing such a material with a pulse laser of ultraviolet light at a wavelength of 20 to 400 nm causes a phenomenon called “ablation” to take place. This phenomenon also takes place with the aforementioned gallium nitride.

(Step S114)

In step S114, an element of at least the elements other than an element of the element chip thus removed is mounted on a mounting substrate (which is an LSI substrate here) by transfer from the substrate, the mounting substrate being different from the substrate. For example, as shown in (g) of FIG. 1, temporary bonding to the sapphire substrate is performed with polyimide resin as a thermoplastic adhesive material in the adhesion layer in the present embodiment, and bonding to the mounting substrate 21 is performed. Although (f) of FIG. 1 illustrates one light-emitting element chip 31 being mounted as a replacement, it is possible to replace a plurality of light-emitting element chips 31. Further, in the mounting step, each element chip is mounted on the mounting substrate while relative coordinates of the plurality of elements are maintained. The term “maintain” here is not limited solely to meaning that no change is effected at all in the relative coordinates, but also encompasses a case where a change is effected in the relative coordinates within a predetermined acceptable error range.

Next, in transferring to the mounting substrate 21, alignment is performed by performing bonding in confirmation of electrical continuity while keeping electrodes of the light-emitting element chips 31 and electrodes of the LSI substrate serving as the mounting substrate 21 in contact with each other in addition to alignment by camera images. By thus performing alignment by camera images and alignment in confirmation of electrical continuity through electrode contacts, more highly precise alignment can be performed, so that mounting yields are improved. This is especially effective in a case where the electrodes have sizes of, for example, 10 micrometers or smaller or, furthermore, 5 micrometers or smaller. Alternatively, there is a method for confirming electrical continuity by providing the elements and the mounting substrate with additional electrodes not electrically connected to the elements. Providing the additional electrodes separately to each of the elements or each of the element chips results in larger element or element chip sizes, thus ending up with a larger array device. It is therefore preferable to perform alignment with electrodes electrically connected to the elements. Note, however, that an increase in size of the array device can be kept to the minimum by providing the electrodes at the outermost periphery of the substrate (the outermost periphery of the array device or, preferably, a unit larger than that, e.g. the outermost periphery of the wafer on which the elements are provided). Further, further preferably, the additional electrodes for alignment are removed after use in the step and do not remain in the final product. The foregoing configuration makes it possible to mount the element chips on the basis of electrical continuity as well as camera images in the inspecting step, thus making it possible to improve the accuracy of position with which the element chips are mounted and to reduce defects in the element chips thus mounted.

Gold-to-gold bonding is performed via gold-plated bumps between the electrodes of the light-emitting element chips 31 and the electrodes of the LSI substrate serving as the mounting substrate 21. The gold-plated bumps are formed on the LSI substrate side. The gold-plated bumps may be provided on the light-emitting element chip 31 side. Although the mounting substrate 21 (LSI substrate) has been described here, gold-plated bumps are formed on electrodes of LSI substrates that are in the form of a wafer such as that shown in FIG. 3, and sapphire substrates (of sizes of display devices or a sapphire wafer size; in view of substrate warpage or the like in some cases, of manufacturable and efficient sizes such as 1/2 sizes, 1/3 sizes, 1/4 sizes, or other sizes of a display device or sizes twice, three times, or more times as large as that of a display device) provided with light-emitting element chips 31 having electrodes at least surfaces of which are composed of gold are bonded via the gold-plated bumps.

(Step S116)

Next, in step S116, for example, as shown in (h) of FIG. 1, spaces between the light-emitting element chips 31 and the LSI substrate, which is the mounting substrate 21, and spaces between the light-emitting element chips 31 are filled with a resin material 51 of a silicone-based thermosetting type.

The resin material 51 used here protects the bump bonds of the light-emitting element chips 31 and, in a subsequent step of detaching the sapphire substrate, which is the translucent substrate 11a, also serves to reduce damage to the mounting substrate 21 (LSI substrate), as the step involves the use of a pulse laser of far-ultraviolet rays having high energy. Accordingly, it is preferable to provide the resin material 51 before a step of removing the sapphire substrate, which is the translucent substrate 11a.

Replacement of light-emitting element chips 31 after the mounting is exercised as a final resort, and replacement of light-emitting element chips is more easily exercised by removing the light-emitting element chip 32 of a rank other than the desired rank, such as a defective light-emitting element chip, before the mounting, as it is difficult to remove the light-emitting element chips 31 since the resin material 51 is present between the light-emitting element chips 31 and the LSI substrate, which is the mounting substrate 21, and between the light-emitting element chips 31 and since the light-emitting element chips 31 are electrically bonded through metallic bonds by the bump material. Furthermore, replacement by light-emitting element chips of the desired rank at a stage prior to the mounting offers an advantage in that the resin material is easily provided in a subsequent step to reduce damage to the mounting substrate and damage to bump bond parts caused by laser irradiation in a case where the after-mentioned substrate removing step is executed.

(Steps S118 and S120)

Next, in steps S118 and 5120, the translucent substrate 11a (sapphire substrate) is removed. For example, as shown in (h) and (i) of FIG. 1, the surface of the translucent substrate 11a (sapphire substrate) opposite to the surface on which the element chips are provided is irradiated with a pulse laser using ultraviolet light of nearly 250 nm, and the light-emitting element chip 31 subjected to temporary bonding with polyimide resin and the light-emitting element chips 31 formed on the translucent substrate 11a (sapphire substrate) are both detached, whereby detachment of the translucent substrate 11a (sapphire substrate) is performed. As has been previously explained, the adhesion layer needs only be removable by being made of a material that is capable of temporary bonding and that has properties such as photo-curability, a thermosetting property, water solubility, and decomposability, and since the gallium nitride of the bond part between an unreplaced light-emitting element chip and the translucent substrate 11a (sapphire substrate) and the adhesion layer of the bond part between a replacement light-emitting element chip and the translucent substrate 11a (sapphire substrate) can both be detached, the manufacturing steps can be favorably simplified by utilizing a breakup phenomenon of the material. Note, however, that depending on the material of which the adhesion layer is made, more proper detachment can be attained by irradiating an unreplaced light-emitting element chip 31 and a temporarily-bonded replacement light-emitting element chip 31 under different conditions; therefore, in that case, it is preferable to set irradiation conditions separately. In the example shown here, the sapphire substrate, which is the translucent substrate 11a, is removed. A reason for this is that even though the substrate exhibits translucency, removal of the substrate allows a display device, a floodlight projector, or the like to extract much light. Since the substrate exhibits translucency, an improved light transmission is attained by thinly processing the substrate by grinding, etching, or the like instead of removing the substrate; however, it is preferable that the substrate be completely removed, as doing so makes it possible to extract much light.

Embodiment 1 is especially effective in the manufacture of a small-sized high-definition display device, and is also effective in the manufacture of a small-sized high-luminance lighting device.

Further, the foregoing configuration makes it possible to remove an element chip of a rank other than the desired rank in a removing step prior to mounting in the manufacture of an array device having a plurality of elements mounted in an array on a mounting substrate. For this reason, there is no need to mount element chips one by one. This makes it possible to remarkably shorten mounting time, and makes it possible to easily obtain high yields of array devices.

Further, Embodiment 1 makes it possible to easily peel an element chip provided on the substrate from the substrate through the energy of light and therefore makes it possible to easily and certainly remove the element chip.

### Modification of Embodiment 1

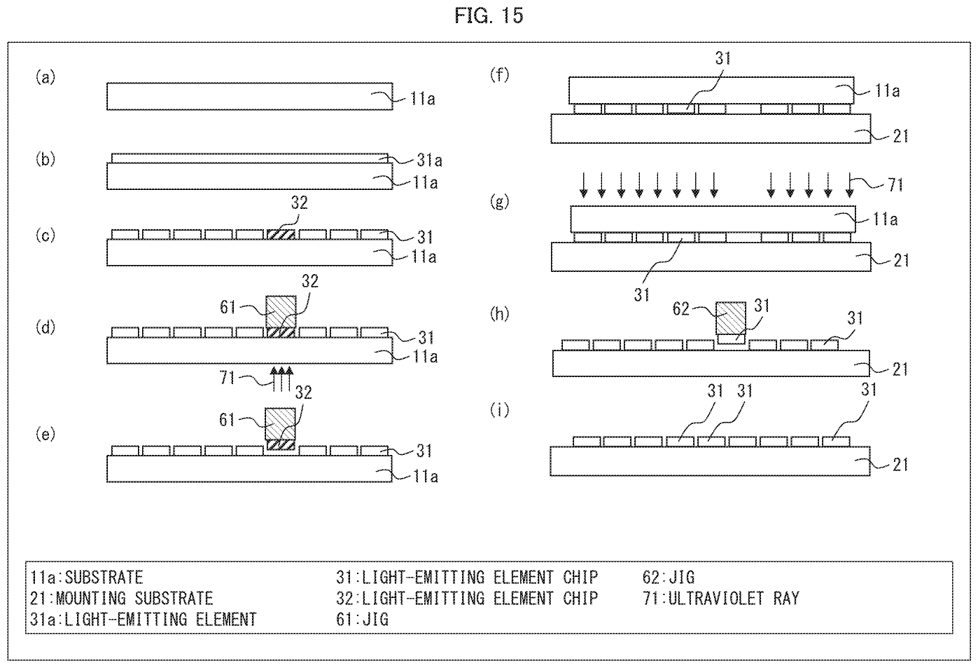

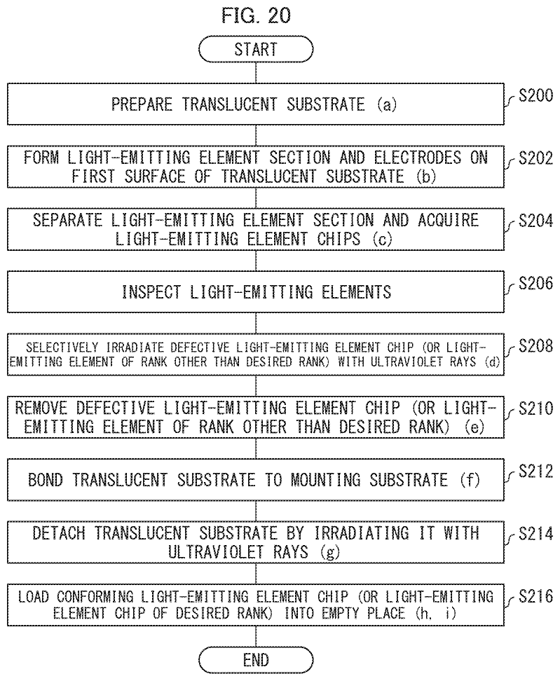

The foregoing description has dealt with a method by which to, before the mounting step of mounting onto the mounting substrate 21 after removal of a light-emitting element chip 32 of a rank other than the desired rank on the substrate, replace the light-emitting element chip 32 with a light-emitting element chip 31 by loading a light-emitting element chip of the desired rank into a space on the substrate from which the element chip was removed. However, this is not intended to limit the present invention, and as a method according to a modification of Embodiment 1, a method by which to complete a replacing step on the mounting substrate 21 is described as shown in FIGS. 15 and 20.

(Steps S200 to S210)

Steps S200 to S210 (steps (a) to (e) of FIG. 15) are identical to steps S100 to S110 (steps (a) to (e) of FIG. 1) of Embodiment 1.

(Step S212)

In the next step S212 (step (f) of FIG. 15), the translucent substrate 11a is bonded to a mounting substrate 21 in a state where the light-emitting element chip of a rank other than the desired rank, such as one that fails to light, have been removed without loading onto the translucent substrate 11a of a light-emitting element chip of the desired rank.

(Step S214)

In the next step S214, as shown in (g) of FIG. 15, the surface of the sapphire substrate, which is a translucent substrate, opposite to the surface on which the elements are provided is entirely irradiated with light, whereby the sapphire substrate is removed.

The light irradiation involves irradiation with a pulse laser of nearly 250 nm with slight shifts in position. At this point in time, the surface of the sapphire substrate opposite to the surface on which the light-emitting elements are provided is not entirely irradiated but selectively irradiated except for the light-emitting element removal region, whereby a further reduction of irradiation time can be achieved than by entirely irradiating the surface of the sapphire substrate opposite to the surface on which the light-emitting elements are provided. This also makes it possible to reduce damage to the LSI substrate, which is the mounting substrate 21. After that, the replacing step is completed through the loading step of loading a light-emitting element chip 31 of the desired rank into an empty space (on the substrate from which the light-emitting element chip 32 was removed) on the mounting substrate with the suction jig 61 or 62 or the like. Note, however, that in comparison with this case, it is more preferable to go as far as to replace element chips on the substrate, which is different from the mounting substrate, at a stage prior to the mounting. This is true in a case where the step of removing the substrate is executed. A reason for this is that a thermosetting type of resin material hardly softens once cured and makes it difficult to load a light-emitting element chip from above the resin material, although providing the resin material before the substrate removing step brings about an effect of making it possible to reduce the load on the bump bond parts at the time of substrate detachment and making it possible to reduce damage to the mounting substrate 21 caused by the laser beam. This problem can be addressed by a method that involves the use of a hotmelt type of resin. This makes it possible to reduce damage to the mounting substrate 21 caused by the laser irradiation.

It is advisable that the manufacturing apparatus have the following functions. A suction jig that is substantially equal in size to a light-emitting element chip 32 provided on the first surface of the sapphire substrate, which is the translucent substrate 11a, is brought into contact with and sticks by suction to the light-emitting element chip 32, and the surface of the sapphire substrate opposite to the surface on which the elements are provided is selectively irradiated with a laser beam on the basis of an inspection result including positional information of the light-emitting element chip 32, so that the light-emitting element chips 32 of specifications other than the desired specifications, such as one that fails to light, can be removed. Furthermore, it is advisable that a mask having an opening be able to be aligned on the basis of an inspection result including positional information. The inspecting step has been described here as a separate step; however, if the manufacturing apparatus has a function that acquires and records an inspection result including positional information, one manufacturing apparatus can be achieved.

(Step S216) In step S216, a light-emitting element chip 31 of the desired rank (conforming item) is loaded by the suction jig 62 into an empty place on the mounting substrate 21 from which the element chip (defective element chip) 32 of a rank other than the desired rank was removed ((h) and (i) of FIG. 15). Note here that in step S216, too, as mentioned above in step S112, after the removing step, an element chip of the desired rank is loaded onto the substrate on the basis of the result of the inspecting step. A specific method that is adopted in this case conforms to the contents of the description of step S112.

### Embodiment 2

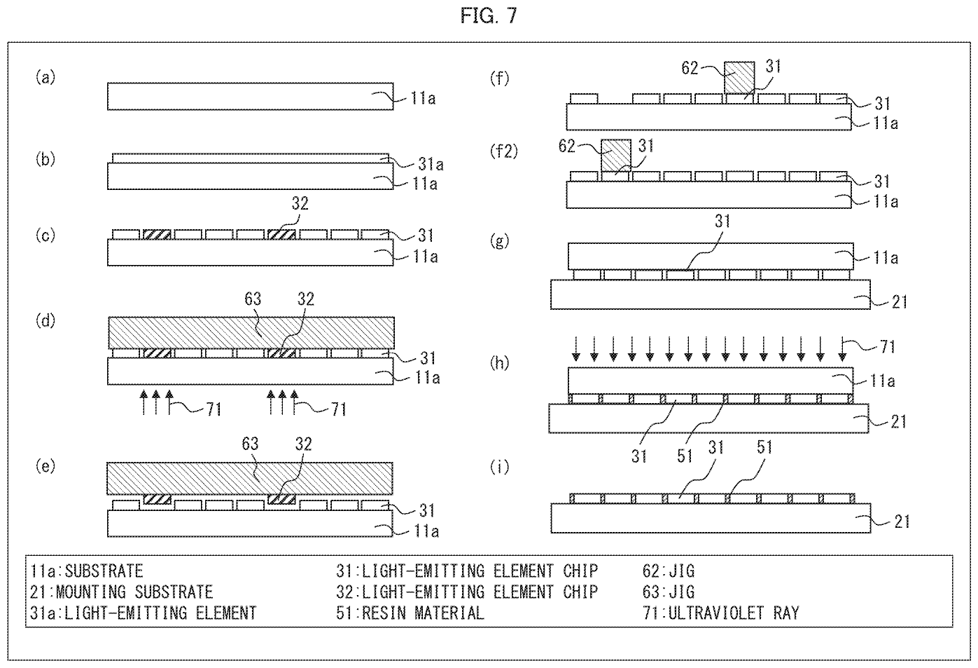

Next, Embodiment 2 is described with reference to FIG. 7. In removing a light-emitting element chip 32 of specifications out of the desired range of specifications, such as one that fails to light, on the first surface of the sapphire substrate, Embodiment 1 uses the suction jig 61, which is substantially equal in size to the light-emitting element chip 32. On the other hand, as shown in (d) of FIG. 7, Embodiment 2 uses a suction jig 63 of a size equal to the size of a plurality of light-emitting element chips, the size of a display device, or the size of a larger substrate or the sapphire substrate, which is a translucent substrate. Embodiment 2 is identical to Embodiment 1 except that the suction jig 63 used in Embodiment 2 is different in size from the suction jig 61 used in Embodiment 1.

As the suction jig 63 becomes larger in size, more light-emitting element chips can be removed at once, so that further improvement in production speed is brought about. As in the case of Embodiment 1, the suction jig 61, which has substantially the same size as a light-emitting element chip, ends up removing light-emitting element chips one by one. On the other hand, the method of Embodiment 2 is more preferable, as it makes it possible to, in a case where there are a plurality of light-emitting element chips of specifications out of the desired range of specifications, remove a plurality of light-emitting element chips 32 at once. Note, however, that in a case where the substrate is remarkably warped or other cases, it is preferable to choose a size in consideration of the magnitude of the warpage; therefore, it is advisable to choose an appropriate size, such as a ½ size, ⅓ size, ¼ size, or other sizes of a display device or a size substantially the same as that of a light-emitting element chip or, in view of production efficiency, a size twice, three times, or more times as large as that of a display device or, furthermore, a wafer size. In the present embodiment, too, the bonding power between a light-emitting element chip 32 of a rank out of the desired range of ranks and the sapphire substrate is weakened by selectively irradiating only the light-emitting element chip 32 with radiation falling on a second surface of the translucent substrate 11a (sapphire substrate) on the basis of an inspection result including positional information of the light-emitting elements in the inspecting step, so that a plurality of the light-emitting element chips 32 can be removed at once by the suction jig 63, which has a size larger than the size of a light-emitting element chip.

At this point in time, as in the case of Embodiment 1, such relationships hold that the translucent substrate 11a (sapphire substrate) is greater than the suction jig 63 in terms of bonding power with respect to the light-emitting element chips 31 and the suction jig 63 is greater than the translucent substrate 11a (sapphire substrate) in terms of bonding power with respect to the light-emitting element chips 32.

Embodiment 2, too, makes it possible to easily obtain high yields of array devices.

### Modification of Embodiment 2

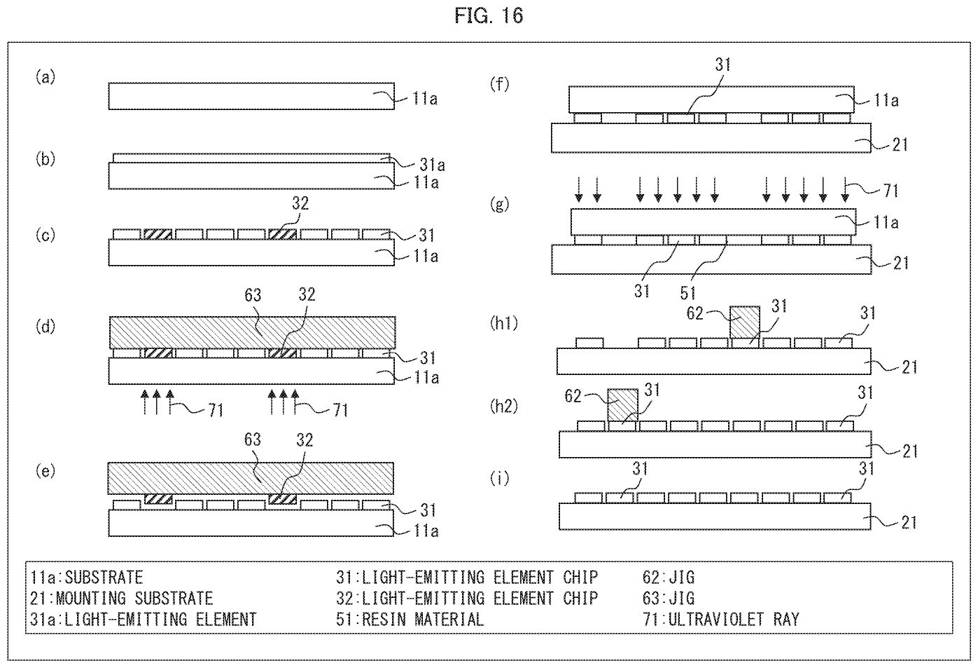

Embodiment 2 has described a method by which to, before the mounting step of mounting onto the mounting substrate 21 after removal of light-emitting element chips 32 of a rank other than the desired rank on the substrate, replace the light-emitting element chips 32 with light-emitting element chips 31 by loading light-emitting element chips of the desired rank into spaces on the substrate from which the light-emitting element chips 32 were removed. However, as an alternative method, a method by which to complete a replacing step on the mounting substrate 21 is described as shown in FIG. 16.

Steps (a) to (e) of FIG. 16 are identical to steps (a) to (e) of FIG. 7. However, in step (f), the light-emitting element chips are transfer-mounted onto the mounting substrate 21 in a state where the light-emitting element chips of a rank other than the desired rank, including those which fail to light, have been removed without being replaced by light-emitting element chips of the desired rank. The surface of the sapphire substrate, which is the translucent substrate 11a, opposite to the surface on which the elements are placed is entirely irradiated with light, whereby the substrate is removed. It is advisable that light irradiation involve irradiation with a pulse laser of nearly 250 nm with slight shifts in position. At this point in time, the second surface is not entirely irradiated but selectively irradiated except for the light-emitting element removal region, whereby a further reduction of irradiation time can be achieved than by entirely irradiating the second surface of the sapphire substrate. This also makes it possible to reduce damage to the LSI substrate, which is the mounting substrate 21 ((g) of FIG. 16).

After that, the replacing step is completed by loading the desired light-emitting element chips 31 onto the LSI substrate, which is the mounting substrate 21, with the suction jig 61 or 62 or the like ((h1), (h2), and (i) of FIG. 16). Note, however, that in comparison with this case, it is more preferable to go as far as to replace element chips on the substrate, which is different from the mounting substrate, at a stage prior to the mounting. This is true in a case where the substrate removing step is executed, and providing the resin material 51 before the substrate removing step brings about an effect of making it possible to reduce the load on the bump bond parts at the time of substrate detachment and making it possible to reduce damage to the mounting substrate 21 caused by the laser beam. However, a thermosetting type of resin material hardly softens once cured and makes it difficult to load a light-emitting element chip from above the resin material. This problem can be addressed by a method that involves the use of a hotmelt type of resin. This makes it possible to reduce damage to the mounting substrate 21 caused by the laser irradiation.

It is advisable that the manufacturing apparatus have the following functions. The suction jig 63, which is substantially equal in size to the translucent substrate 11a (sapphire substrate), is brought into contact with and sticks by suction to light-emitting element chips 32 provided on the first surface of the sapphire substrate, which is the translucent substrate 11a, and the second surface of the translucent substrate 11a (sapphire substrate) is selectively irradiated with a laser beam on the basis of an inspection result together with positional information of the light-emitting element chips 32, so that the light-emitting element chips 32 of specifications other than the desired specifications, including those which fail to light, can be removed. Furthermore, it is advisable that a mask having an opening be able to be aligned on the basis of an inspection result including positional information. The inspecting step has been described here as a separate step; however, if the manufacturing apparatus has a function that acquires and records an inspection result including positional information, one manufacturing apparatus can be achieved. The manufacturing apparatus used in Embodiment 1 needs only be subjected to replacement of the suction jig.

### Embodiment 3

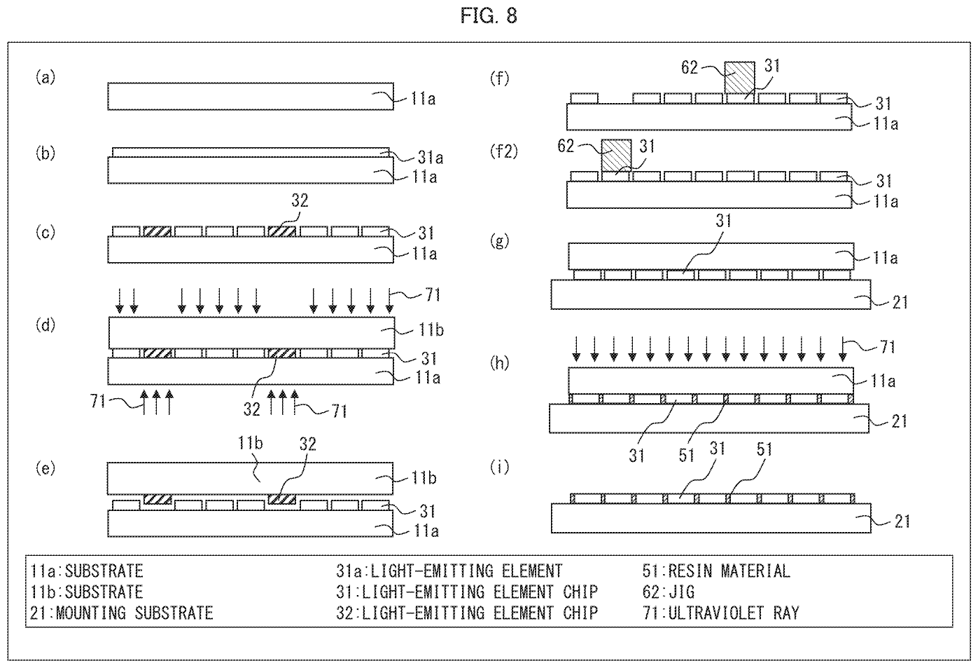

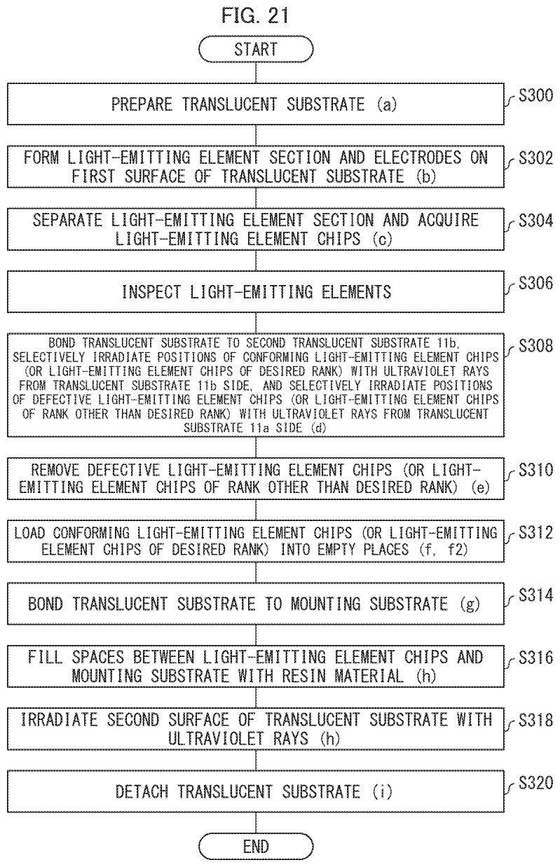

Next, Embodiment 3 is described with reference to FIGS. 8 and 21. In Embodiment 2, the suction jig 63, whose size is larger than the size of a light-emitting element chip, e.g. the suction jig 63, which is substantially equal in size to the translucent substrate 11a (sapphire substrate), is used in removing light-emitting element chips 32 of specifications out of the desired range of specifications, including those which fail to light, on the first surface of the translucent substrate 11a (sapphire substrate). On the other hand, the present embodiment uses a substrate having a size larger than the size of a light-emitting element chip, e.g. a translucent substrate 11b that is substantially equal in size to the sapphire substrate. In this case, as in the case of Embodiment 2, a variety of modifications, such as a size equal to that of a display device, are possible, and need only be chosen in consideration of the influence of the warpage of the substrate.

(Steps S300 to S306) Steps S300 to S304 are identical to steps S100 to S104 of Embodiment 1 ((a) to (c) of FIG. 8 are identical to (a) to (c) of FIG. 7).

First, in step S300, a translucent substrate 11a is prepared ((a) of FIG. 8). Next, in step S302, a thin film 30 is subjected to crystal growth on a first surface of the translucent substrate 11a, and from this thin film, a light-emitting element section and electrodes are formed ((b) of FIG. 8). In step S304, a light-emitting element section is separated to form light-emitting element chips ((c) of FIG. 8). After that, in step S306, the light-emitting element chips thus formed are inspected. Note, however, that the inspecting step may take place after step S302 or step S304.

(Step S308)

In step S308, a translucent substrate 11b is bonded to the translucent substrate 11a. Then, the positions of light-emitting element chips 32 of a rank other than the desired rank are selectively irradiated with ultraviolet rays from the translucent substrate 11a side, and the positions of light-emitting element chips 31 of the desired rank are selectively irradiated with ultraviolet rays from the translucent substrate 11b side ((d) of FIG. 8). This causes the light-emitting element chips 31 of the desired rank to adhere to the translucent substrate 11a and causes the light-emitting element chips 32 of a rank other than the desired rank to adhere to the translucent substrate 11b.

(Step S310)

In step S310, the translucent substrate 11a and the translucent substrate 11b are separated from each other, whereby the light-emitting element chips 32 of a rank other than the desired rank are removed from the translucent substrate 11a ((e) of FIG. 8).

(Step S312) In step S312, light-emitting element chips 31 of the desired rank are loaded by a jig 62 into the places from which the light-emitting element chips 32 of a rank other than the desired rank were removed ((f) and (f2) of FIG. 8). Note here that in step S312, too, as mentioned above in step S112, after the removing step, light-emitting element chips of the desired rank (conforming items) are loaded onto the substrate on the basis of the result of the inspecting step. A specific method that is adopted in this case conforms to the contents of the description of step S112.

(Step S314)

In step S314, the translucent substrate 11a, loaded with only the light-emitting element chips 31 of the desired rank, is bonded to a mounting substrate 21 ((g) of FIG. 8).

(Step S316)

In step S316, spaces between the light-emitting element chips and the mounting substrate are filled with a resin material 51 ((h) of FIG. 8).

(Step S318) In step S318, the element chips are transferred to the mounting substrate 21 by irradiation with ultraviolet rays falling on a surface of the translucent substrate 11a opposite to the surface on which the element chips are placed ((h) of FIG. 8).

(Step S320) In step S320, the translucent substrate 11a is removed from the mounting substrate ((i) of FIG. 8).

The translucent substrate 11b is for example a glass substrate. An adhesion layer (not illustrated) is provided on a first surface of the translucent substrate 11b (glass substrate). The adhesion layer is bonded to the light-emitting element chips 31 and 32 on the translucent substrate 11a (sapphire substrate). On the basis of an inspection result including positional information in the inspecting step, the positions of the light-emitting element chips 32 that fail to light or the light-emitting element chips 32 of a rank other than the desired rank are selectively irradiated with a laser beam at a wavelength of, for example, 250 nm from the sapphire substrate side, and the light-emitting element chips 31 falling within the desired range of specifications are selectively irradiated with light from the translucent substrate 11b side. In Embodiment 3, selective irradiation with light can be done not only from the translucent substrate 11a (sapphire substrate) side but also from the translucent substrate 11b side by using the translucent substrate 11b instead of the suction jig 61. This makes it possible to more certainly remove the light-emitting element chips 32. That is, such relationships easily hold that the translucent substrate 11a is greater than the translucent substrate llb in terms of bonding power with respect to the light-emitting element chips 31 and the translucent substrate 11b is greater than the translucent substrate 11a in terms of bonding power with respect to the light-emitting element chips 32. Note, however, that even in the case of selective irradiation only from either of the substrate sides, the relationships need only hold ((d) and (e) of FIG. 8). The subsequent steps are identical to the steps described with reference to FIG. 7 in Embodiment 2.

Embodiment 3 makes it possible to easily obtain high yields of array devices with narrow spacings between elements.

### Modification of Embodiment 3

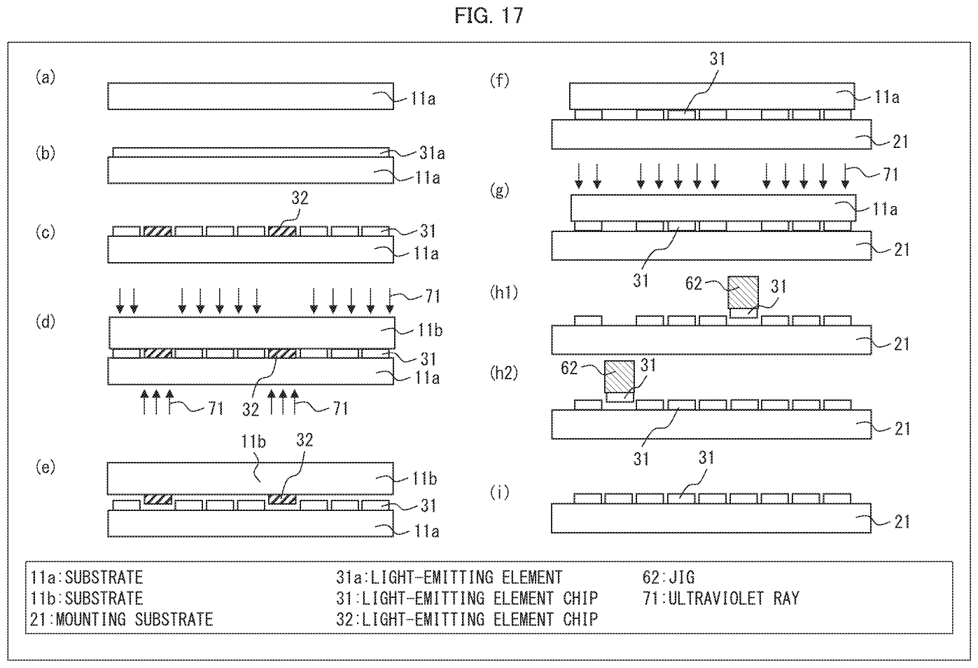

Embodiment 3 has described a method by which to, before the mounting step of mounting onto the mounting substrate 21 after removal of light-emitting element chips 32 of a rank other than the desired rank on the substrate, replace the light-emitting element chips 32 with light-emitting element chips 31 by loading light-emitting element chips of the desired rank into spaces on the substrate from which the light-emitting element chips 32 were removed. However, as an alternative method, a method by which to complete a replacing step on the mounting substrate 21 is described as shown in FIG. 17.

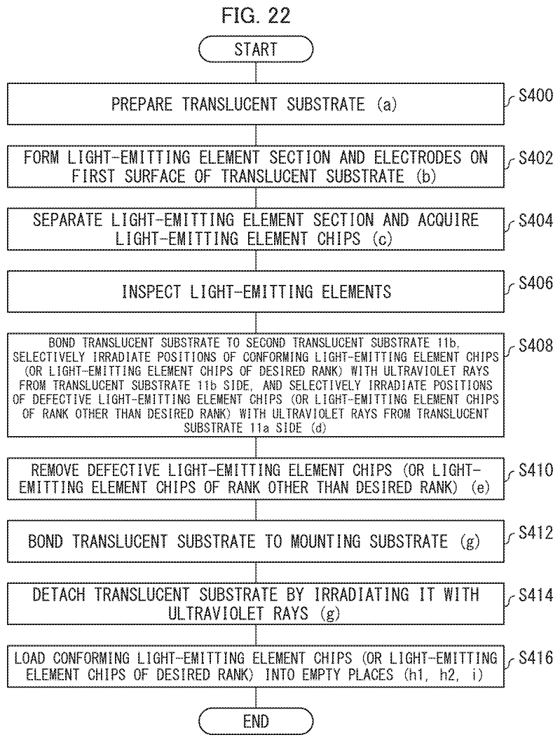

FIG. 22 is a flow chart explaining steps of the present modification. The following describes differences between the present modification and Embodiment 3 with reference to FIGS. 17 and 22.

(Steps S400 to S410)

Steps S400 to S410 of the present modification are identical to steps S300 to S310 of Embodiment 3.

(Step S412)

In next step S412, the translucent substrate 11a is bonded to a mounting substrate 21 with the light-emitting element chips 32 of a rank other than the desired rank removed from the translucent substrate 11a, and the light-emitting element chips 31 of the desired rank are transferred to the mounting substrate 21 ((g) of FIG. 17).

(Step S414)

In next step S414, the translucent substrate 11a is detached from the mounting substrate 21 by irradiation with ultraviolet rays falling on the surface of the translucent substrate 11a opposite to the surface on which the element chips are placed ((g) of FIG. 17).

(Step S416)

In next step S416, light-emitting element chips 31 of the desired rank are loaded into the empty places on the mounting substrate 21 to which no element chips have been transferred ((h1), (h2), and (i) of FIG. 17). Note here that in step S416, too, as mentioned above in step S112, after the removing step, light-emitting element chips of the desired rank (conforming items) are loaded onto the substrate on the basis of the result of the inspecting step. A specific method that is adopted in this case conforms to the contents of the description of step S112.

(a) to (e) of FIG. 17, which show steps of the present modification, are identical to (a) to (e) of FIG. 8; however, in step (f), the light-emitting element chips are transfer-mounted onto the mounting substrate 21 in a state where the light-emitting element chips of a rank other than the desired rank, including those which to fail to light, have been removed without being replaced by light-emitting element chips of the desired rank. The surface of the sapphire substrate, which is a translucent substrate, opposite to the surface on which the elements are placed is entirely irradiated with light, whereby the substrate is removed. It is advisable that the light irradiation involve irradiation with a pulse laser of nearly 250 nm with slight shifts in position. At this point in time, the surface opposite to the surface on which the elements are placed is not entirely irradiated but selectively irradiated except for the light-emitting element removal region, whereby a further reduction of irradiation time can be achieved than by entirely irradiating the second surface of the sapphire substrate. This also makes it possible to reduce damage to the LSI substrate, which is the mounting substrate 21 ((g) of FIG. 17). After that, the replacing step is completed by loading the desired light-emitting element chips 31 onto the LSI substrate, which is the mounting substrate 21, with the suction jig 61 or 62 or the like ((h1), (h2), and (i) of FIG. 17). Note, however, that in comparison with this case, it is more preferable to go as far as to replace element chips on the substrate, which is different from the mounting substrate, at a stage prior to the mounting. This is true in a case where the step of removing the substrate is executed. A reason for this is that a thermosetting type of resin material hardly softens once cured and makes it difficult to load a light-emitting element chip from above the resin material, although providing the resin material 51 before the substrate removing step brings about an effect of making it possible to reduce the load on the bump bond parts at the time of substrate removal and making it possible to reduce damage to the mounting substrate 21 caused by the laser beam. This problem can be addressed by a method that involves the use of a hotmelt type of resin. This makes it possible to reduce damage to the mounting substrate 21 caused by the laser irradiation. In that case, although the effect of protecting the bump bond parts is reduced since the resin easily softens at the time of transfer mounting, the bump bond parts can be protected during later handling.

### Another Modification of Embodiment 3

The transparent substrate 11b, which has been used in the description so far, may be substituted with a nontransparent substrate.

Similarly, an adhesion layer (not illustrated) is provided on a first surface of the nontransparent substrate. Such relationships need only be set to hold that the translucent substrate 11a is greater than the nontransparent substrate in terms of bonding power with respect to the light-emitting element chips 31 and the nontransparent substrate is greater than the translucent substrate 11a in terms of bonding power with respect to the light-emitting element chips 32. Note, however, that the use of the translucent substrate 11b, which transmits light, makes it easy to establish the relationships and therefore makes it easy to more certainly achieve the bonding power relationships.

It is advisable that the manufacturing apparatus have the following functions. A substrate having a size larger than the size of a light-emitting element chip, e.g. the translucent substrate 11b, provided with the adhesion layer on the first surface thereof, which is substantially equal in size to the sapphire substrate, is pressed against light-emitting element chips 32 provided on the first surface of the sapphire substrate, which is the translucent substrate 11a, and the second surface of the sapphire substrate is selectively irradiated with a laser beam on the basis of an inspection result including positional information of the light-emitting element chips 32, so that the light-emitting element chips 32 of specifications other than the desired specifications, including those which fail to light, can be removed. Furthermore, it is advisable that a mask having an opening be able to be aligned on the basis of an inspection result including positional information. Doing so allows finer selective irradiation and therefore makes it easy to remove the light-emitting element chips 32. In this case, a non-translucent substrate can be used instead of the substrate 11b. However, the use as the substrate 11b of a substrate that exhibits translucency allows selective irradiation from both the second surface of the translucent substrate 11a and a second surface of the translucent substrate 11b on the basis of an inspection result including positional information of the light-emitting element chips 31 and the light-emitting element chips 32, thereby making it possible to more certainly execute the step of removing a light-emitting element chip. That is, such relationships are favorably easily set to hold that the translucent substrate 11a is greater than the substrate 11b in terms of bonding power with respect to the light-emitting element chips 31 and the translucent substrate 11b is greater than the substrate 11a in terms of bonding power with respect to the light-emitting element chips 32. Unlike in the case of the manufacturing apparatus used in Embodiment 2, selective irradiation with light from the translucent substrate 11b side can be done; that is, it is advisable to have a mechanism from both the translucent substrate 11a side and the translucent substrate 11b side and replace the suction jig with the substrate 11b provided with the adhesion layer, or a jig provided with an adhesion layer will do. The inspecting step has been described here as a separate step; however, if the manufacturing apparatus has a function that acquires and records an inspection result including positional information, one manufacturing apparatus can be achieved.

### Embodiment 4

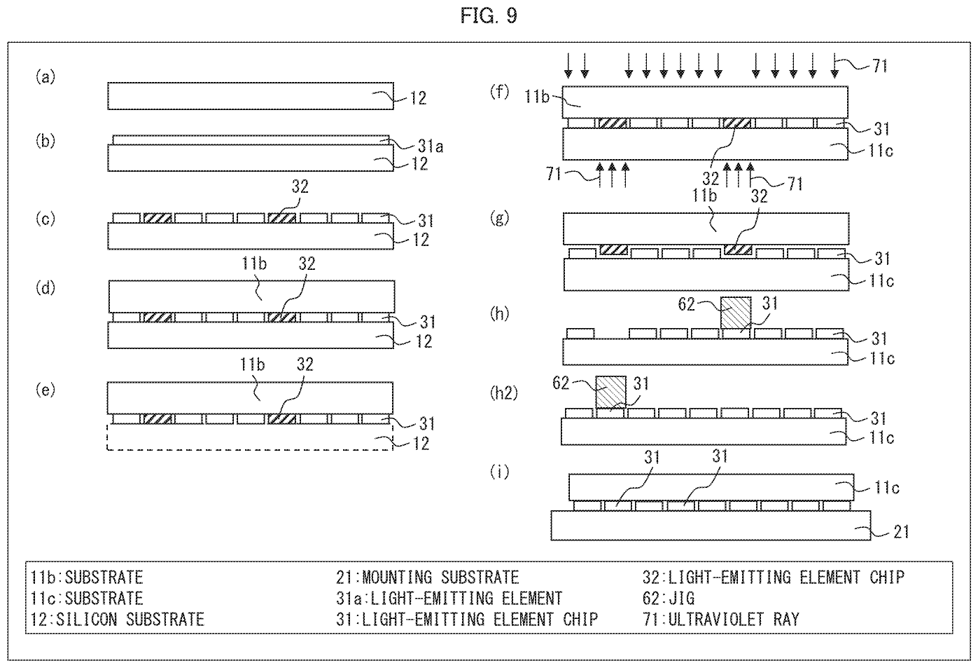

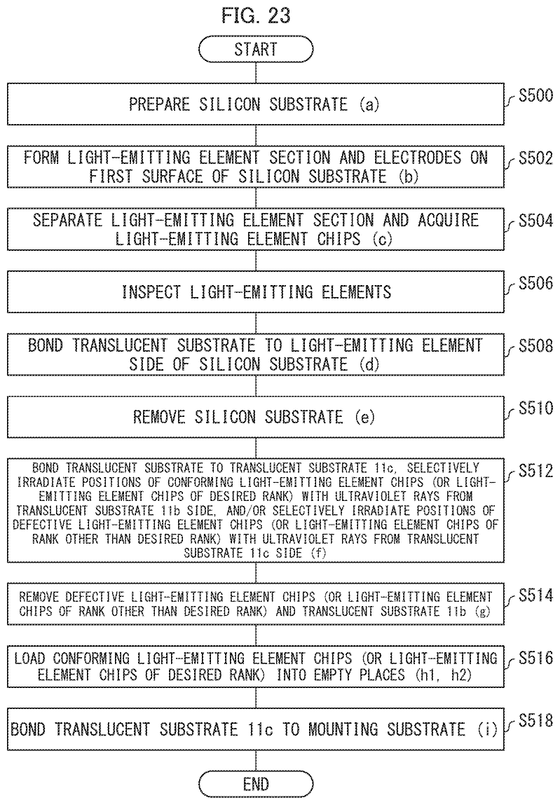

The description has been given so far by using the sapphire substrate as the substrate or the translucent substrate 11a. The present embodiment shows examples of the translucent substrate 11a other than the sapphire substrate with reference to FIGS. 9 and 23.

The translucent substrate may be a flexible resin substrate, provided it has light transmission properties; however, in consideration of the accuracy of position with which the light-emitting element chips are transferred, it is preferable that the translucent substrate be a rigid resin substrate or a glass substrate. In the example shown here, a glass substrate is used, as it is harder to deform and higher in accuracy of position during transfer than a resin substrate. Further, a case where light-emitting elements 31a are formed not on a sapphire substrate but on a silicon substrate is described below with reference to FIG. 23.

(Step S500)

First, in step S500, a silicon substrate 12 is prepared ((a) of FIG. 9; the numbers of the steps shown in FIG. 9 being hereinafter enclosed in parentheses).

(Step S502)

Next, in step S502, a desired film is subjected to crystal growth on a first surface of the silicon substrate 12, and an elaborate forming process such as photolithography is used to form light-emitting elements 31a and electrodes electrically connected to the light-emitting elements (b).

(Step S504)

In step S504, the light-emitting elements formed on the silicon substrate 12 are separated into units of single or multiple light-emitting elements 31a to form light-emitting element chips 31. In so doing, the separation can be made by dicing a region free of the light-emitting elements 31a with a dicing blade or a laser or by performing dry etching. The present example employs a dry etching method, which makes it easy to form the light-emitting elements 31a at narrow spacings (c).

(Step S506)

In step S506, the light-emitting elements are inspected. Note, however, that the step of inspecting the light-emitting elements may take place after step S502 or step S504.

(Step S508)

Next, in step S508, a translucent substrate is bonded to the silicon substrate 12 (d).

(Step S510)

In step S510, the silicon substrate 12 is removed (e).

(Steps S512 and S514)

In step S512, a translucent substrate 11c is bonded to the translucent substrate 11b. Thus, in a placing step, light-emitting element chips 31 subjected to element separation may be provided on the substrate. That is, the placing step and the element separating step may be executed in any order. Next, element chips of the desired rank are selectively irradiated with ultraviolet rays falling on a surface of the translucent substrate 11b opposite to the surface on which the elements are provided, and/or the positions of defective light-emitting element chips (or light-emitting element chips of a rank other than the desired rank) may be selectively irradiated with ultraviolet rays from the translucent substrate 11c side. In step S514, the translucent substrate 11b is peeled from the translucent substrate 11c, whereby the light-emitting element chips 32 of a rank other than the desired rank adhere to the translucent substrate 11b and the light-emitting element chips 31 of the desired rank adhere to the translucent substrate 11c (f, g).

(Step S516)

Next, in step S516, element chips 31 of the desired rank are loaded into the empty places on the translucent substrate 11c into which no element chips 31 of the desired rank have been loaded ((h), (h2)). Note here that in step S516, too, as mentioned above in step S112, after the removing step, light-emitting element chips of the desired rank (conforming items) are loaded onto the substrate on the basis of the result of the inspecting step. A specific method that is adopted in this case conforms to the contents of the description of step S112.

(Step S518)

Next, in step S518, the translucent substrate 11c, loaded with the element chips 31 of the desired rank, is bonded to a mounting substrate 21, and the element chips 31 of the desired rank are transferred to the mounting substrate 21 (i).

In the present embodiment, the glass substrate, which is the translucent substrate 11b, is bonded to the silicon substrate 12 so that an adhesion layer provided on a first surface of the translucent substrate 11b faces the light-emitting elements (d). Next, the silicon substrate 12 is removed by grinding, dry etching, wet etching, or the like (e). The light-emitting elements are inspected after (b) or (c). The inspecting step includes causing the light-emitting elements 31 to emit light and measuring and recording the intensity and wavelength of the light and, furthermore, a forward voltage (Vf) or the like. Specifications are drawn up in advance separately for use in each of types, models, or the like of product, and on the basis of measurement data, elements falling within a desired range of specifications (rank) are used in a display device. In so doing, light-emitting element chips are replaced on the basis of mapping data obtained by mapping for each of the positions of the light-emitting elements 31a. In so doing, the light-emitting elements can be classified into two ranks, namely light-emitting elements that fail to light and light-emitting elements that light. This makes it possible to remove the light-emitting elements that fail to light, thus making it possible to achieve higher yields of display devices. Furthermore, it is more preferable that only light-emitting elements 31a (display elements) that are close in rank to one another be assembled to manufacture one array device 201 or 202 (display device), as doing so reduces luminance unevenness and color unevenness of the array device 201 or 202 (display device), and it is therefore more preferable to manufacture high-quality display devices by rank. Next, an adhesion layer is provided on a first surface of a glass substrate serving as the translucent substrate 11c, which is a different substrate, and pasted to the light-emitting elements 31a on the translucent substrate 11b, and on the basis of an inspection result (including positional information), the regions of light-emitting element chips 31 falling within the desired range of specifications are irradiated with light from the translucent substrate 11b (glass substrate) side, whereby the light-emitting element chips 31 of the desired specifications are transferred to the translucent substrate 11c (glass substrate). For that purpose, the adhesion layers need only be selected so that the adhesion layer of the translucent substrate 11b is stronger in bonding power than the adhesion layer of the translucent substrate 11c. Further, since the translucent substrate 11c is used as the substrate, it is preferable to selectively irradiate the regions of the light-emitting element chips 32 from the translucent substrate 11c side, too. A reason for this is that that way makes it easy to cause such relationships to hold that the translucent substrate 11c is greater than the translucent substrate 11b in terms of bonding power with respect to the light-emitting element chips 31 and the translucent substrate 11b is greater than the translucent substrate 11c in terms of bonding power with respect to the light-emitting element chips 32. In a case where the relationships easily hold, it is preferable not to perform selective irradiation from the translucent substrate 11c side, as not doing so makes it simple without the need to provide another adhesion layer between the translucent substrate 11c and the light-emitting element chips 31 to be loaded in subsequent steps (h) and (h2). Next, light-emitting elements 31a of the desired specifications are loaded by the hitherto described suction jig 61 into the regions on the translucent substrate 11c (glass substrate) where no transfer took place. In a case where selective irradiation has been done from the translucent substrate 11c side in step (g), the light-emitting element chips to be loaded need to be provided with adhesion layers in steps (h) and (h2). These adhesion layers may be the same as the adhesion layer provided entirely on the translucent substrate 11C. Note, however, that in a case where the substrate 11c is removed after subsequent step (i), a relationship at the time of removal, i.e. such a relationship that the mounting substrate 21 is greater than the translucent substrate 11 in terms of bonding power with respect to the light-emitting element chips 31, needs to be set to hold.

Embodiment 4 makes it possible to obtain high yields of array devices in comparatively expensive products such as display devices and lighting devices.

### Modification of Embodiment 4

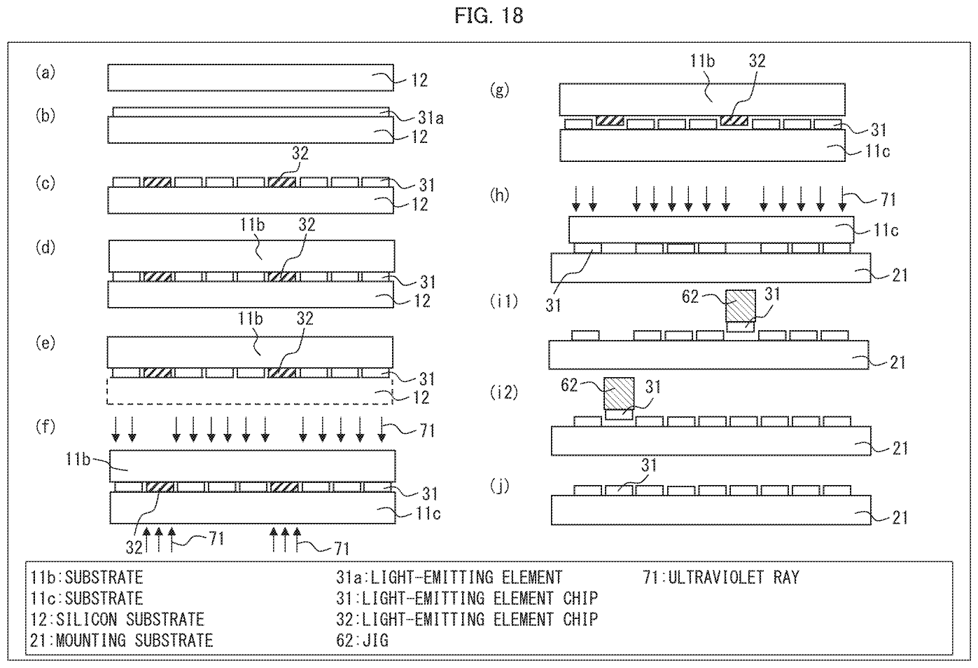

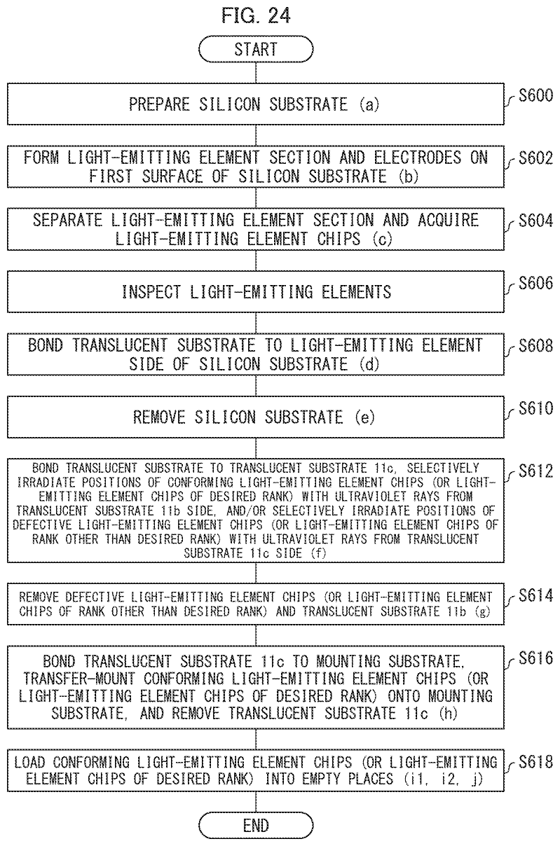

Embodiment 4 has described a method by which to, before the mounting step of mounting onto the mounting substrate after removal of light-emitting element chip 32 of a rank other than the desired rank on the substrate, replace the light-emitting element chip 32 with light-emitting element chips 31 by loading light-emitting element chips of the desired rank into spaces on the substrate from which the light-emitting element chip 32 were removed. However, as an alternative method, a method by which to complete a replacing step on the mounting substrate is described as shown in FIG. 18. The following describes manufacturing steps of the present modification with reference to FIGS. 18 and 24.

(Steps S600 to S614)

Steps S600 to S614 are the same as steps S500 to S514 of Embodiment 4.

(Step S616)

In step S616, the translucent substrate 11c is bonded to a mounting substrate 21, and light-emitting elements of the desired rank are transferred to the mounting substrate 21. After that, the translucent substrate 11c is detached from the mounting substrate ((h) of FIG. 18).

(Step S618)

In step S618, light-emitting element chips 31 of the desired rank are mounted into places on the mounting substrate into which no element chips have been loaded ((i1), (i2), and (j) of FIG. 18). Note here that in step S618, too, as mentioned above in step S112, after the removing step, light-emitting element chips of the desired rank (conforming items) are loaded onto the substrate on the basis of the result of the inspecting step. A specific method that is adopted in this case conforms to the contents of the description of step S112.

(a) to (g) of FIG. 18 are identical to (a) to (e) of FIG. 9; however, in step (h), the light-emitting element chips are transfer-mounted onto the mounting substrate 21 in a state where the light-emitting element chips of a rank other than the desired rank, including those which fail to light, have been removed without being replaced by light-emitting element chips 31 of the desired rank. The second surface of the translucent substrate 11c is entirely irradiated with light, whereby the substrate is removed. It is advisable that the light irradiation involve irradiation with a pulse laser of nearly 250 nm with slight shifts in position. At this point in time, the second surface is not entirely irradiated but selectively irradiated except for the light-emitting element removal region, whereby a further reduction of irradiation time can be achieved than by entirely irradiating the second surface of the translucent substrate 11c ((h) of FIG. 18). After that, the replacing step is completed by loading the desired light-emitting element chips 31 onto the LSI substrate, which is the mounting substrate 21, with the suction jig 61 or 62 or the like ((i1), (i2), and (j) of FIG. 18). Note, however, that in comparison with this case, it is more preferable to go as far as to replace element chips on the substrate, which is different from the mounting substrate, at a stage prior to the mounting. This is true in a case where the step of detaching the substrate is executed. A reason for this is that a thermosetting type of resin material hardly softens once cured and makes it difficult to load a light-emitting element chip from above the resin material, although providing the resin material before the substrate detaching step brings about an effect of making it possible to reduce the load on the bump bond parts at the time of substrate detachment and making it possible to reduce damage to the mounting substrate caused by the laser beam. This problem can be addressed by a method that involves the use of a hotmelt type of resin. This makes it possible to reduce damage to the mounting substrate 21 caused by the laser irradiation. In that case, although the effect of protecting the bump bond parts is reduced since the resin easily softens at the time of transfer mounting, the bump bond parts can be protected during later handling.

### Embodiment 5

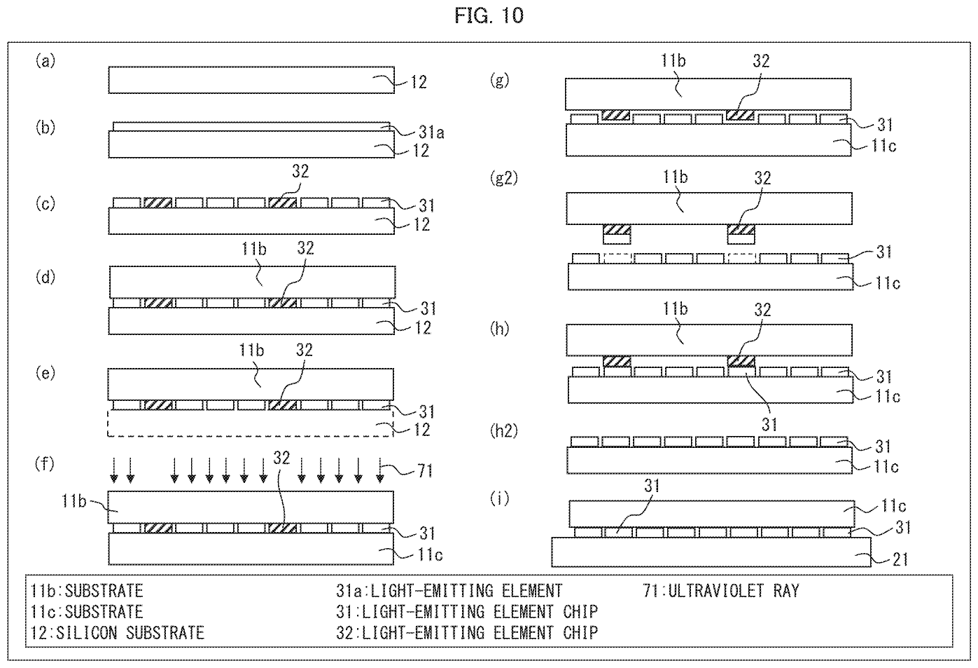

In the present embodiment, the removing step includes removing defective element chips 32 from the substrate 11c by attaching the defective element chips 32 to a second translucent substrate 11b that is different from the substrate 11c. Further, the loading step of the present embodiment includes an attaching step ((g2) of FIG. 10) of further attaching element chips 31 of a desired quality onto the defective element chips 32 attached to the second translucent substrate 11b and a transferring step ((h) of FIG. 10) of transferring the element chips 31 of the desired quality attached to the second translucent substrate 11b onto the substrate 11c on the basis of positional information of the defective element chips 32 removed from the substrate and thereby replacing the defective element chips 32 thus removed with the element chips 31 of the desired quality.

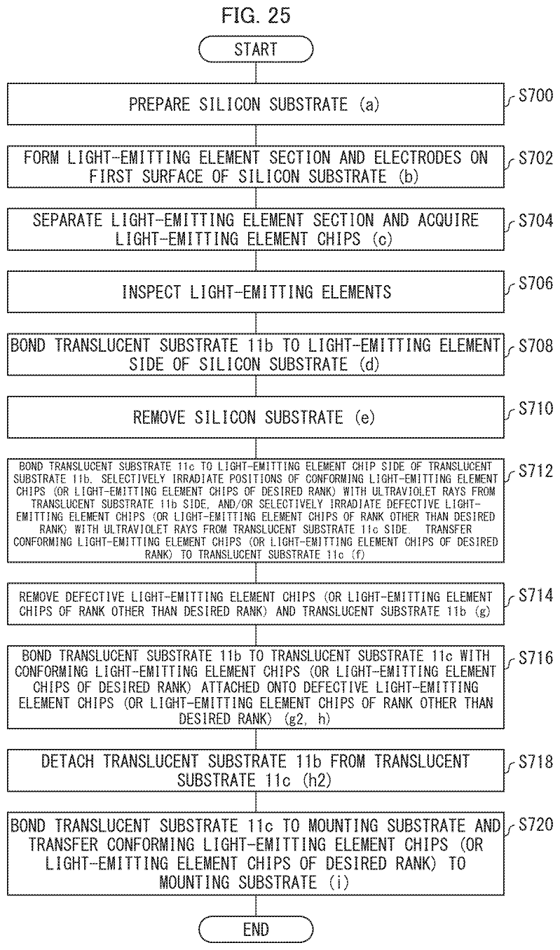

FIG. 25 is a flow chart showing steps of manufacturing an array device according to the present embodiment. The following describes the manufacturing steps of the present embodiment with reference to FIGS. 10 and 25.

(Step S700)

In step S700, a silicon substrate 12 is prepared ((a) of FIG. 10; the numbers of the steps shown in FIG. 10 being hereinafter enclosed in parentheses).

(Step S702)

Next, in step S702, a light-emitting element section and electrodes are formed on a first surface of the silicon substrate (b).

(Step S704)

In step S704, the light-emitting element section is separated to form light-emitting element chips (c).

(Step S706)

In step S706, the light-emitting element chips thus formed are inspected. Note, however, that this step may take place after step S702 or step S704.

(Step S708)

In step S708, a translucent substrate 11b is bonded to the surface of the silicon substrate 12 on which the light-emitting elements are formed (d).

(Step S710)

In step S710, the silicon substrate 12 is removed from the translucent substrate 11b (e).

(Step S712)

In step S712, a second translucent substrate 11c is bonded to the translucent substrate 11b. Thus, in a placing step, light-emitting element chips 31 subjected to element separation may be provided on the substrate. That is, as in the case of step S512 described above, the placing step and the element separating step may be executed in any order. Then, element chips of the desired rank are selectively irradiated with ultraviolet rays falling on a surface of the translucent substrate 11b that does not face the translucent substrate 11c, and/or the positions of defective light-emitting element chips (or light-emitting element chips of a rank other than the desired rank) are selectively irradiated with ultraviolet rays from the translucent substrate 11c side. As a result, the element chips of the desired rank are transferred to the translucent substrate 11c (f).

(Step S714)

In step S714, the translucent substrate 11b is removed from the translucent substrate 11c together with the defects (i.e. the element chips of a rank other than the desired rank) (g).

(Step S716)

In step S716, the translucent substrate 11b is bonded to the translucent substrate 11c with light-emitting element chips of the desired rank (or conforming light-emitting element chips) attached onto the light-emitting element chips of a rank other than the desired rank (or the defective light-emitting element chips) (g2 and h). In this step, the light-emitting elements of the desired rank attached onto the light-emitting elements of a rank other than the desired rank on the translucent substrate 11b are loaded into the placed on the translucent substrate 11c into which no light-emitting elements have been loaded. In step S716, too, as mentioned above in step S112, after the removing step, light-emitting element chips of the desired rank are loaded onto the substrate on the basis of the result of the inspecting step. A specific method that is adopted in this case conforms to the contents of the description of step S112.

(Step S718)

In step S718, the translucent substrate 11b is detached from the translucent substrate 11c (h2).

(Step S720)

In step S720, the translucent substrate 11c, loaded with the conforming items (i.e. the light-emitting elements of the desired rank), is bonded to a mounting substrate (i). As a result, the light-emitting elements of the desired rank are loaded onto the mounting substrate.

In (h) and (h2) of FIG. 9 described above in Embodiment 4, the light-emitting element chips 31 are loaded onto the translucent substrate 11c by using the suction jig 62. On the other hand, such a state is used that the light-emitting element chips 32 are removed from the translucent substrate 11c in step (g) without using the suction jig 62 and the light-emitting element chips 32 are loaded onto the translucent substrate 11b, which is removed at that time. That is, the description of steps (a) to (g) of FIG. 10 with reference to FIG. 10 is identical to the description of steps (a) to (g) of FIG. 9 used in Embodiment 4; however, first, in step (g2), the light-emitting element chips 32 thus removed are bonded to the translucent substrate 11b, and the translucent substrate 11c is loaded with light-emitting element chips 31 of the desired rank on the light-emitting element chips 32 via adhesion layers. These adhesion layers need only be capable of temporary tacking, and it is advisable to use adhesion layers that are much weaker in bonding power than the adhesion layers for loading onto the translucent substrate 11c. Next, the light-emitting element chips 31 are pasted to the translucent substrate 11c with an adhesion layer provided on the first surface thereof. At this point in time, for example, a water-soluble adhesive material is provided on the light-emitting element chips 32 on the translucent substrate 11b, and an adhesive material composed of a thermoplastic polyimide resin is provided on the first surface of the translucent substrate 11c. After the light-emitting element chips 31 have been pasted to the translucent substrate 11c, the water-soluble adhesive material, by which the light-emitting element chips 31 are temporarily tacked on the light-emitting element chips 32 on the translucent substrate 11b, can be detached by being dipped in heated water. In this way, only the light-emitting element chips 31 falling within the desired range of specifications are loaded onto the translucent substrate 11c ((h) and (h2)). Transfer-mounting the light-emitting element chips 31 onto the mounting substrate 21 completes display devices as array devices at a high yield rate.

### Embodiment 6

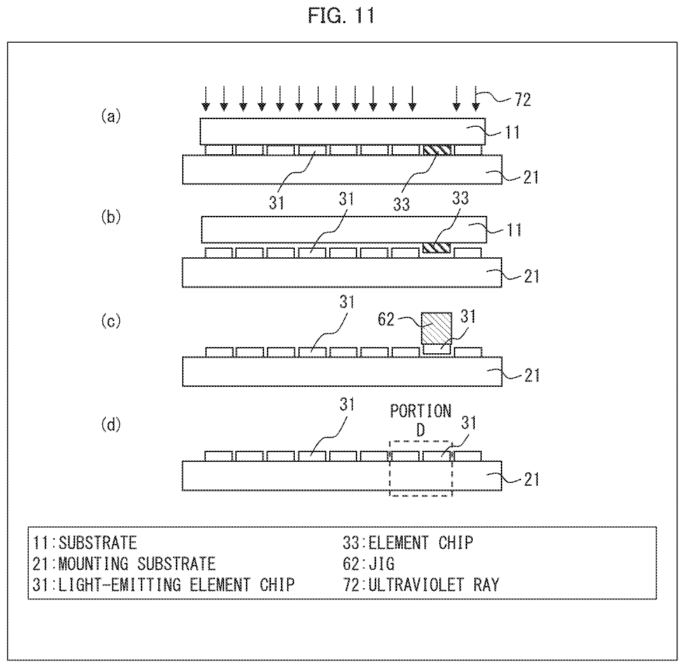

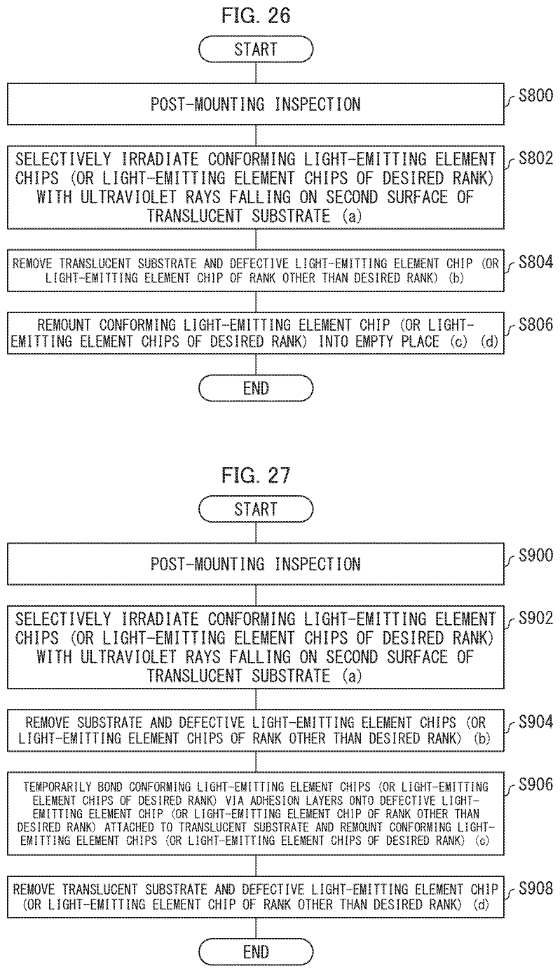

Embodiments 1 to 5, which have been described so far, have illustrated manufacturing methods and apparatuses that complete a replacing step on a substrate that is different from the mounting substrate or complete a replacing step by removing a light-emitting element chip 32 from a substrate that is different from the mounting substrate and loading a light-emitting element chip onto the mounting substrate 21. However, the present embodiment further includes a post-mounting inspecting step of, after the mounting step, determining whether an element chip that has been mounted is defective. Further, in the present embodiment, the substrate removing step after the mounting step includes removing the substrate and selectively removing a defective element chip on the basis of a result of a post-mounting inspecting step. An example of application to a step of remounting for a post-mounting mounting defect is described with reference to FIGS. 11 and 26.

(Step S800)

Step S800 and its subsequent steps take place after step S114 of Embodiment 1 (FIG. 19). Further, (a) of FIG. 11 shows a step subsequent to (g) of FIG. 7, (g) of FIG. 8, (i) of FIG. 9, or (i) of FIG. 10.

In step S800, a post-mounting inspection is carried out. (Step S802)

In step S802, a defective element chip 33 that has been mounted is removed with reference to an inspection result of the post-mounting inspecting step. Then, if there is a defect, the defective light-emitting element chip 33 is replaced by a light-emitting element chip 31 of a desired level. The term “mounting defect” here is equivalent to a case where an electrode of the mounting substrate 21 is not successfully bonded or a poor appearance such as such as a chipped or cracked light-emitting element chip 31.

Once the light-emitting element chip 33, which is a mounting defect that has been mounted on the mounting substrate 21, is identified on the basis of the inspection result, a region other than the light-emitting element chip 33, which is a mounting defect, is selectively irradiated with light falling on the surface of the translucent substrate 11 opposite to the surface on which the elements are placed ((a) of FIG. 11; the numbers of the steps shown in FIG. 11 being hereinafter enclosed in parentheses).

(Step S804)

In step S804, the substrate 11 and the light-emitting element chip 33 are removed ((b)).

(Step S806)

In step S806, a light-emitting element chip 31 of the desired rank is remounted onto the mounting substrate 21 ((c), (d)). Note here that in step S806, too, as mentioned above in step S112, after the removing step, a light-emitting element chip of the desired rank (conforming item) is loaded onto the substrate on the basis of the result of the inspecting step. A specific method that is adopted in this case conforms to the contents of the description of step S112.

The translucent substrate 11 of the present embodiment may be a sapphire substrate as shown in Embodiments 1 to 3 or may be a glass substrate as shown in Embodiments 4 and 5.

Alternatively, the translucent substrate 11 may be a glass substrate to which light-emitting element chips 31 formed on a sapphire substrate have been transferred an even number of times. A reason for this is that transferring from the sapphire substrate to the glass substrate, which is close in coefficient of linear expansion to the mounting substrate 21 than the sapphire substrate, is preferable when it is easy to perform transfer at the time of mounting that entails heating. For example, a reason for this is that in a case where the mounting substrate 21 is an LSI substrate composed of silicon and gold-plated bumps on the LSI substrate are bonded to electrodes (gold) of the light-emitting element chips, there is a need for heating to approximately 300° C.; therefore, in that case, using borosilicate glass instead of sapphire makes it easy to perform alignment at the time of bonding with a small difference in coefficient of linear expansion, as silicon has a coefficient of linear expansion of 3.9×10⁻⁶/° C. as compared with the coefficient of linear expansion of 9×10⁻⁶/° C. of soda lime, the coefficient of linear expansion of 3.3×10⁻⁶/° C. of borosilicic acid, coefficient of linear expansion of 0.6×10⁻⁶/° C. of quartz, and coefficient of linear expansion of 7 to 8×10⁻⁶/° C. of sapphire. Even when the translucent substrate 11 is a sapphire substrate, mounting may be done from the sapphire substrate, provided the mounting substrate 21 is a soda-lime substrate, which is comparatively close in coefficient of linear expansion to the sapphire substrate. More preferably, it is more preferable to transfer from the sapphire substrate to the soda-lime substrate. Note, however, that in consideration of the sizes of the electrodes and bumps to be bonded or the like, there is no need to increase transferring steps, provided the sizes are comparatively large. In this way, an appropriate choice needs only be made based on a combination of materials of the mounting substrate 21 and the substrate 11.

In a case where the translucent substrate serving as the substrate 11 is a sapphire substrate, selective detachment of an (unreplaced) light-emitting element chip 31 provided on a first surface of the sapphire substrate can be done by weakening the bond between the unreplaced light-emitting element chip 31 and the sapphire substrate by decomposing a gallium nitride layer into gallium and nitrogen by irradiation with a pulse laser at a wavelength of approximately 250 nm. Further, selective detachment of a light-emitting element 31 attached by means of an adhesion layer through the replacing step can be done, too, by weakening the bond between the light-emitting element chip 31 and the sapphire substrate by weakening the adhesiveness of the adhesion layer by irradiation with light. For example, the step can be favorably easily executed at the same wavelength and intensity as the unreplaced light-emitting element chip 31. Note, however, that separately irradiating an unreplaced light-emitting element chip 31 to be replaced and a replacement light-emitting element chip 31 with light at proper intensities and wavelengths brings about improvement in detachability from the translucent substrate 11, making it possible to certainly remove only a defective light-emitting element chip 33. At this point in time, an electrode of the mounting substrate 21 and an electrode of the light-emitting element 33 are electrically bonded to each other via a bump, and the light-emitting element chip 33 is fixedly surrounded as appropriate by the resin material 51. At this point in time, such relationships are set to hold that the mounting substrate 21 is greater than the translucent substrate 11 in terms of bonding power with respect to the light-emitting element chips 31 and the translucent substrate 11 is greater than the mounting substrate 21 in terms of bonding power with respect to the light-emitting chip 33.

In a step subsequent to (i) of FIG. 15, (i) of FIG. 16, (i) of FIG. 17, or (j) of FIG. 18, a different translucent substrate provided with an adhesive layer is bonded to peel only a light-emitting element chip 33. This makes it possible to remove the light-emitting element chip 33 by selective irradiation of only the regions of the light-emitting element chips 31 from the second surface, vacuum suction with the suction jig 61 or 62, or the adhesion layer.

At this point in time, too, such relationships are set to hold that the mounting substrate 21 is greater than the translucent substrate 11 (or the suction jig 61 or 62) in terms of bonding power with respect to the light-emitting element chips 31 and the translucent substrate 11 (or the suction jig 61 or 62) is greater than the mounting substrate 21 in terms of bonding power with respect to the light-emitting chip 33.

A remounting step of, after the post-mounting removing step, mounting an element chip of a desired quality onto the mounting substrate with a paste material containing conductive particles is further included.

In a case where the resin material 51 provided is of a hotmelt type, the bond with the light-emitting element chip 33 can be weakened by heating the resin material to the glass transition temperature or melting point of the resin material or higher during or after irradiation with a pulse laser ((a) and (b) of FIG. 11). Next, a light-emitting element chip 31 of the desired rank is remounted in the position of the light-emitting element chip 33 removed with the suction jig 62 ((c) of FIG. 11), whereby high yields of display devices are obtained. In so doing, in a case where the resin material 51 is provided, bonding may be done at or above the glass transition temperature or melting point of the resin material 51 and at a temperature at which bump bonding is possible. The resin material 51 sets when cooled down to normal temperature; therefore, although the resin material 51 becomes less effective in protecting the bump bond parts at the time of peeling of the substrate 11, the resin material 51 can protect the bump bond parts during later handling.

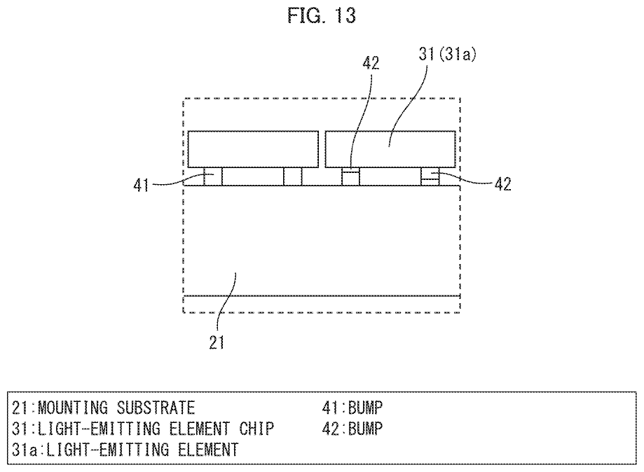

Note here that FIG. 13 is an enlarged view of a portion D of FIG. 11. Although the bumps 41 have level differences after removal of the light-emitting element 33, the level differences can be corrected by applying a paste material containing conductive particles to the level differences with an inkjet apparatus. The present example uses, as the bump material, the gold-plated bumps 41 provided on the mounting substrate, and uses, as the paste material containing conductive particles at the time of remounting, a paste material containing a gold nanoparticle material. Although the nanoparticle particle binder may be resin, using a solvent that evaporates before the end of bonding can bring about improvement in electrical conductivity after the bonding. The use of the nanoparticle material makes even the fine bumps 41 almost free of defects such as electrical short circuits, and the high active force makes bonding possible at a low temperature of approximately 150 to 250° C. Furthermore, the use of the nanoparticle material is suitable to a case where the bumps 41 have minute diameters of 10 micrometers or smaller or, furthermore, 5 micrometers or smaller. By increasing the bump diameters so that the bonding strength of the bumps 41 and 42 satisfies the bonding power relationships, normalization is performed so that the relational expressions hold. In using the nanoparticle material at the time of remounting, it is preferable to perform the remounting without providing the resin material 51 and provide the resin material 51 as appropriate after the remounting. For example, in a case where an array device is manufactured as a display device, the resin material 51 acts to break up light from each light-emitting element. The resin material 51 may be made of any of various materials; however, by being made of a material containing silicone or acrylic resin, the resin material 51 can have improved resistance to light emitted by the light-emitting elements.

The foregoing configuration makes it possible to easily additionally supply a new bump material even in the case of variations in height of the bumps after element chip removal, allowing mounting at substantially the same degree of parallelization as an unreplaced element chip. Further, even in the case of the same metal as bumps in a bulk state, the heating temperature can be set to a low temperature at the time of remounting. This makes it possible to minimize the effect on the bond part of the unreplaced element chip.

The resin material 51 is provided by a method for injecting the resin material 51 into the spaces between the light-emitting element chips and the spaces between the light-emitting element chips and the mounting substrate 21 at a stage subsequent to mounting via the bumps before step (a) of FIG. 11, or by providing the resin material 51 in advance on the mounting substrate 21 side or the translucent substrate 11 side before mounting with the bumps formed in advance on at least either the mounting substrate 21 or the light-emitting element chips 31, performing electrical bonding, and filling the spaces between the light-emitting element chips and the spaces between the light-emitting element chips and the mounting substrate 21 with the resin material 51 spread wet. The aforementioned ACF, ACP, NCF, or NCP are used in bonding after being thus provided as the resin material 51 in advance.

Alternatively, the resin material 51 may be provided after the substrate removing step. For protection of bump connections and protection of the mounting substrate at the time of substrate peeling, it is advisable that the resin material 51 be provided before at least the substrate peeling.

In removing a defectively-mounted element chip and replacing it with an element chip of the desired quality after mounting element chips onto the mounting substrate, Embodiment 6 makes it possible to directly use the positional information of the element chip thus removed and can therefore make remounting simpler.

### Modification of Embodiment 6

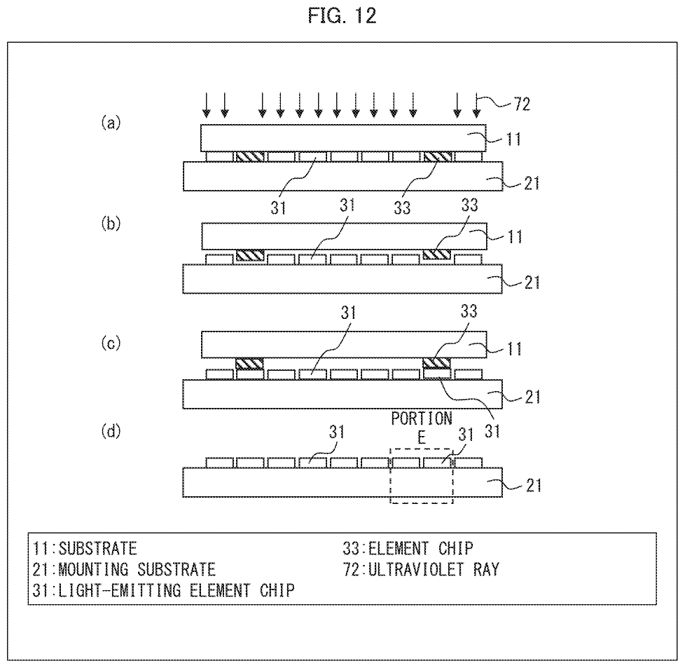

FIG. 12 shows a modification of the manufacturing method of Embodiment 6 shown in FIG. 11. Further, FIG. 27 is a flow chart showing manufacturing steps according to the modification of this embodiment. The modification of Embodiment 6 is described with reference to FIGS. 12 and 27.

In the present modification, the remounting step includes an attaching step of attaching an element chip 31 of a desired quality onto a defective element chip 33 removed from the mounting substrate 21 by using the substrate 11 or a third substrate that is different from the substrate and a transferring step ((c) of FIG. 12) of transferring the element chip 31 of the desired quality attached to the substrate 11 or the third substrate onto the mounting substrate 21 on the basis of positional information of the defective element chip 33 removed from the mounting substrate 21 and thereby replacing the defective element chip 33 thus removed with the element chip 31 of the desired quality.

(Step S900)

First, in step S900, a post-mounting inspection is carried out.

(Step S902)

Next, in step S902, the surface of the translucent substrate 11 opposite to the surface on which the elements are placed is irradiated with light. At this point in time, the regions of the light-emitting element chips 31 of the desired rank are selectively irradiated with light ((a) of FIG. 12; the numbers of the steps shown in FIG. 12 being hereinafter enclosed in parentheses).

(Step S904)

In step S904, the substrate 11 and light-emitting element chips 33 of a rank other than the desired rank are removed from the mounting substrate 21(b).

(Step S906)

Next, in step S906, element chips 31 of the desired rank are temporarily bonded via an adhesive agent onto the defective light-emitting element chips 33 attached to the translucent substrate 11. After that, the mounting substrate 21 and the translucent substrate 11 are bonded to each other, and the element chips of the desired rank are remounted onto the mounting substrate 21(c). Note here that in step S906, too, as mentioned above in step S112, after the removing step, light-emitting element chips of the desired rank are loaded onto the substrate on the basis of the result of the inspecting step. A specific method that is adopted in this case conforms to the contents of the description of step S112.

(Step S908)

Next, in step S908, the translucent substrate 11 and the defective element chips attached thereto are removed from the mounting substrate 21(d).

That is, the present modification is an example of application in which the manufacturing method of FIG. 10 used in the step of removing light-emitting element chips and used in replacing light-emitting element chips 33 with light-emitting element chips 31 is used in the remounting step.

In FIG. 11, light-emitting element chips 31 are remounted one by one by the suction jig 62. Alternatively, in peeling the translucent substrate 11, a plurality of light-emitting element chips 33 can be removed at once by peeling the translucent substrate 11 from the mounting substrate 21 after weakening the bonds between conforming light-emitting element chips 31 and the translucent substrate through selective irradiation of only the conforming light-emitting element chips 31 with light falling on the second surface of the translucent substrate 11 on the basis of an inspection result (including positional information) after the mounting step while maintaining the bonds between the defective light-emitting element chips 33 and the translucent substrate 11 instead of irradiating the defective light-emitting element chips 33. Next, light-emitting element chips 31 are temporarily bonded via adhesion layers onto the light-emitting element chips 33 attached to the translucent substrate 11, and are then remounted. In so doing, too, the plurality of light-emitting element chips 31 can be mounted at once (c). The foregoing steps make it possible to manufacture display devices at a higher yield rate with a reduction of mounting defects, although high yields of display devices can be manufactured through a replacing step alone. As in the case of the steps of FIG. 11 described earlier, FIG. 13 is an enlarged view of the structure of a portion E.

The remounting step of FIG. 11 or 12 may include measuring the states, particularly heights, of bumps from which an element chip 33 was removed and, on the basis of a height measurement result, adjusting the amount of a metal-containing paste material that is supplied. Doing so makes it possible to make a remounted element chip and a non-remounted element chip substantially equal in height, and also makes it possible to reduce heightwise tilts.

The manufacturing apparatus has been described so far as being used in a replacing step including a removing step on a substrate that is different from the mounting substrate and, furthermore, a loading step. The manufacturing apparatus is also applicable to a remounting step. Furthermore, it is more advisable that in the remounting step, the manufacturing apparatus have a function of, in the remounting step, measuring the heights of bumps from which an element chip 33 was removed and/or a function of, in the remounting step, supplying a conductive nanoparticle paste on the basis of a measurement result. It is more advisable that the manufacturing apparatus include both of the functions, although either of the functions may be provided in a different apparatus. These functions are suitable to more easily manufacturing high yields of high-quality array devices with controlled heights and tilts substantially equal to those of unreplaced element chips. In so doing, consideration may also be given to a change in volume through calcination of metal nanoparticles.

The description has been given so far with a focus on an example in which the replacing step is executed on a translucent substrate, the replacing step can also be executed on a non-translucent substrate. As an example, Embodiment 4, which has been described with reference to FIG. 9, is described with the substitution of a non-translucent substrate 11c for the substrate 11c shown in steps (f), (g), (h), and (h2). There is a mixture of light-emitting element chips 31 and light-emitting element chips 32 on the first surface of the translucent substrate 11b. The translucent substrate 11b is pasted to the non-translucent substrate 11c so that the surface on which the light-emitting element chips 31 and 32 are present faces the non-translucent substrate 11c. In so doing, the substrate 11c has an adhesion layer provided on a first surface thereof. After that, on the basis of an inspection result including positional information in an inspecting step executed in advance, only the regions of the light-emitting element chips 31 are selectively irradiated with light from the transparent substrate 11b side ((f) of FIG. 9), and only the light-emitting element chips 31 are transferred to the substrate 11c ((g) of FIG. 9). Next, light-emitting element chips 31 are loaded by a suction jig into the places from which the light-emitting element chips 32 were removed, so that only the light-emitting element chips 31 are arranged on the substrate ((h) and (h2) of FIG. 9).

Next, the light-emitting element chips 31 are mounted onto the mounting substrate 21 with the light-emitting element chips 31 having their electrodes in alignment with the electrodes of the mounting substrate 21. The mounting can be done through bumps ((i) of FIG. 9). Thus, even the non-translucent substrate 21 makes it possible to replace the light-emitting element chips 32 with the light-emitting element chips 31 on the substrate 11c in the replacing step. In the case of a display device, the non-translucent substrate 11c needs to be peeled without fail after the mounting. Therefore, the substrate 11a is provided in advance with an adhesion layer composed of a hotmelt type of resin or an adhesion layer composed of a water-soluble adhesive material. This makes it possible to easily peel the substrate 11c by heating or moisture during or after bonding.

That is, a such a relationship needs only hold that the mounting substrate 21 is greater than the substrate 11c in terms of bonding power with respect to the light-emitting element chips 31. Note, however, that in the replacing step, it is easy to more certainly remove the light-emitting element chips 32, as only the regions of the light-emitting element chips 32 can be selectively irradiated with light from the translucent substrate 11c side in a case where the substrate 11c is the translucent substrate 11c. A reason for this is that transfer is certainly possible because it is possible to ensure a wide range within which such relationships hold that the substrate 11c is greater than the translucent substrate 11b in terms of bonding power with respect to the light-emitting element chips 31 and the translucent substrate 11b is greater than the substrate 11c in terms of bonding power with respect to the light-emitting element chips 32.

While the embodiments described so far have dealt with display devices, a plurality of light-emitting elements can be arranged in an array to be used as an array device such as a lighting device. Note, however, that it is a display device to which pixel defects and variations in luminance of pixels can be fatal, and the replacing step is more effective in manufacturing high yields of display devices. LEDs or surface-emission semiconductor lasers can be used as light-emitting elements in an array device such as a display device or a lighting device.

Although the mounting substrate 21 has been described on the premise that the mounting substrate 21 is a nontransparent substrate such as an LSI substrate, the mounting substrate may alternatively be a translucent substrate such as a glass substrate, a resin substrate, or a flexible substrate.

In removing a defectively-mounted element chip and replacing it with an element chip of the desired quality after mounting element chips onto the mounting substrate, the modification of Embodiment 6, too, makes it possible to directly use the positional information of the element chip thus removed and can therefore make remounting simpler.

<Array Device Manufacturing Repair Apparatus (Repair Apparatus) 100>

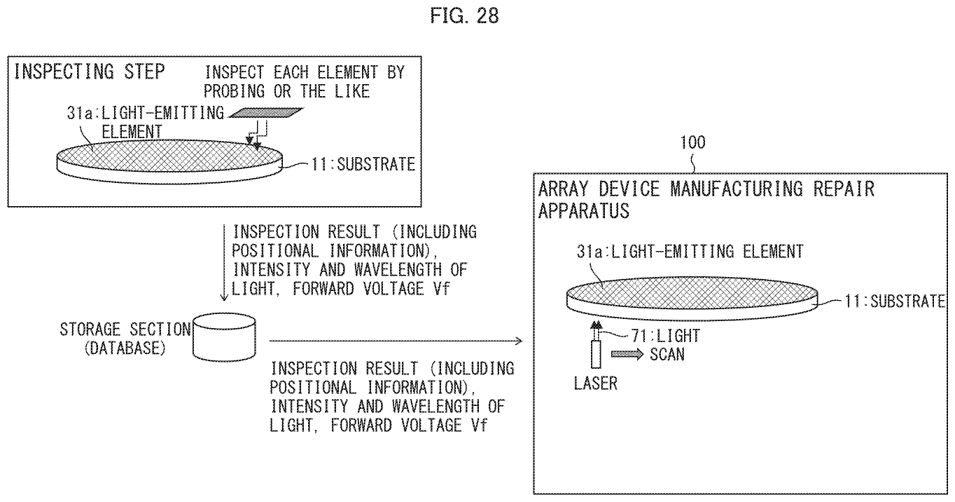

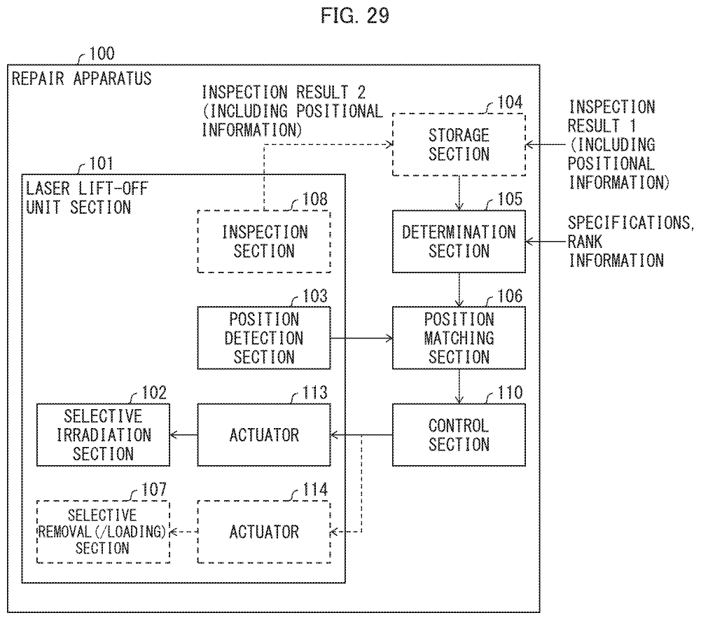

Next, an array device manufacturing repair apparatus 100 according to the present invention is described with reference to FIGS. 28 and 29. FIG. 28 is a diagram for explaining a basic configuration of the array device manufacturing repair apparatus 100, and FIG. 29 is a block diagram showing a configuration of the array device manufacturing repair apparatus. It should be noted that while the array device manufacturing repair apparatus 100 to be described below is an apparatus that is responsible for some of the steps of manufacturing an array device, the array device manufacturing repair apparatus 100 is encompassed in the apparatus for manufacturing an array device as set forth in the claims.

As shown in FIG. 28, the array device manufacturing repair apparatus 100 is basically configured to, in a step of inspecting elements or element chips on a substrate, drive the elements, for example, by bringing a probe pin into contact with electrodes provided on the elements. In a case where the elements are light-emitting elements, data associated with positional information is obtained by measuring the intensity and wavelength of light, a forward voltage Vf, and the like at the time of emission of light, as has been described about the method for manufacturing an array device. The array device manufacturing repair apparatus selects, on the basis of an inspection result (including positional information), an element chip to be removed. While the element chip to be removed needs to be selectively irradiated with light falling on an surface of the substrate opposite to a chip loading surface of the substrate, there are various possible selective irradiation methods, as has been described so far about the method for manufacturing an array device. As an example of a selective irradiation method, FIG. 28 shows a case where the element chip is selectively irradiated with a laser beam through a translucent substrate serving as the substrate. Further, in the case of selective irradiation with a laser beam, there needs to be provided a mechanism that, by moving both or either the substrate on which the element chips are provided and/or a laser irradiation section, can change its relative position in at least a direction parallel to each other's board surfaces (the direction parallel to the board surfaces being hereinafter sometimes called “XY direction”). In order to move or fix the substrate on which the element chips are provided, it is advisable to have a jig configured to hold the substrate by any three or more points on the periphery of the substrate or by the entire periphery around at least an element region of the substrate or a translucent jig and have a mechanism in which the jig moves. As for a light source, for example, a region in which a particular light-emitting element chip is located is selectively irradiated with light 71 at a wavelength of 20 to 400 nm in an ultraviolet range. When the light-emitting element 31a is a gallium nitride element, irradiation with a pulse laser of nearly 250 nm causes gallium nitride nearly up to a level of several tens of nanometers from the translucent substrate 11a (sapphire substrate) to be decomposed into gallium and nitrogen, so that the light-emitting element 31a can be removed from the translucent substrate 11a (sapphire substrate). The use of a pulse laser here is intended to reduce thermal damage to the elements or the like. Accordingly, in the case of elements that are less thermally influenced, a continuous-wave laser may be used. Selective irradiation by laser beam irradiation is divided into two major categories. The first category is to irradiate the position of the element chip to be removed with light for a longer time by carrying out an operation of, while the laser is in an always-light-emitting state, suspending the laser at the position of the element chip and passing the laser over the positions of non-relevant element chips. The second category is to bring the laser into an irradiation ON state at the position of the element chip and bring the laser into an irradiation OFF state (or a lower light intensity state than in the irradiation ON state) at the positions of non-relevant element chips. The term “always-light-emitting or irradiation ON state” refers to a state in which the pulse laser is continuously emitting pulsed light. The term “irradiation OFF state” refers to a state in which no laser irradiation takes place or a state in which the brightness of irradiation is lower than in the irradiation ON state. These two methods may be combined with each other. Further, it is preferable, for shortening of machining time, that the spot diameter d of the laser and the size X of a short side of a rectangular element chip (in the case of a square element chip, the size x of one side) ideally have such a relationship as to be of substantially the same size (d=x); however, the following relationship needs only be set to hold: either d≤x or x≤d and d≤2x. In a case where d≤x, the laser may scan within the range of an element chip size. Further, when a mask obtained by providing an opening (or a light transmission section) in a nontransparent material is further used, the relationship x≤d may hold (without need for the condition d≤2x; however, the size of the opening of the mask is smaller than 2x). In a case where the mask is concomitantly used, it is advisable to have a mechanism that moves in an XY direction with respect to the mask. In the case described here, the light source used is a laser light. Alternatively, the light source used may be an isotropically-diffused light source such as an LED or a lamp. In that case, it is advisable to narrow down light with a lens or the like. In narrowing down with a lens or the like, it is preferable, for shortening of machining time, that d and x ideally have such a relationship as to be of substantially the same size (d=x); however, the following relationship needs only be set to hold: either d≤x or x≤d and d≤2x. In a case where d≤x, the laser may scan within the range of an element chip size. Further, when a mask obtained by providing an opening (or a light transmission section) in a nontransparent material is further used, the relationship x≤d may hold (without need for the condition d≤2x; however, the size of the opening of the mask is smaller than 2x). In this case, it is advisable to have a mechanism that relatively move the light source and the mask from one position to another in the XY direction with respect to the substrate. In a case where no lens is used, the mask needs only be combined. In this case, it is advisable to have a mechanism that relatively moves the mask from one position to another with respect to the substrate in the XY direction. The size of the opening (or the light transmission section) of the mask is substantially the same as the size of the element chip regardless of whether the direction of light is anisotropic (laser beam) or isotropic, and it is advisable to bring the mask as close as possible to the substrate.

Next, the configuration of the array device manufacturing repair apparatus 100 is described with reference to the block diagram of FIG. 29. The block diagram is indicated by solid lines and dotted lines. The solid lines indicate the basic components of the array device manufacturing repair apparatus 100. The dotted lines indicate additional components that are preferably configured in addition to the basic components.

As shown in FIG. 29, the array device manufacturing repair apparatus 100 includes a laser lift-off unit section 101, a storage section 104, a determination section 105, a position matching section 106, and a control section 110. The control section 110 exercises overall control of the apparatus. Further, the laser lift-off unit section 101 of the array device manufacturing repair apparatus 100 includes a selective irradiation section 102, a position detection section 103, and an actuator 113 that actuates each component of the apparatus in accordance with instructions from the control section 110. In a case where the array device manufacturing repair apparatus 100 includes a selective removal(/loading) section 107, the array device manufacturing repair apparatus 100 further includes an actuator 114 that actuates the selective removal(/loading) section 107. The determination section 105 determines, on the basis of an inspection result of each element, whether an element chip separated so as to include one or a plurality elements is removed. Further, on the basis of a determination result yielded by the determination section 105, the selective irradiation section 102 selectively irradiates the element chip with light falling on a second surface of a translucent substrate opposite to a first surface of the translucent substrate on which the element chip is placed.

The array device manufacturing repair apparatus 100 stores, in the storage section 104, an inspection result (inspection result 1 yielded by an external apparatus) including positional information of an element provided on the substrate by a different apparatus. For shortening of time for obtaining an inspection result, it is advisable that the array device manufacturing repair apparatus 100 include the storage section 104. Note, however, that inspection result data may be obtained directly from a different apparatus or different storage means without the array device manufacturing repair apparatus 100 including the storage section 104. These inspection results are determined together with the positional information as to whether the element chips are of the desired rank or of a rank other than the desired rank by setting the specifications and the desired rank of elements and chips in advance for each model or the like in the determination section 105 and classifying the inspection results into ranks of element chips according to the specifications. Meanwhile, the array device manufacturing repair apparatus 100 includes the laser lift-off unit section 101, on which a substrate provided with element chips whose elements are divided into single or multiple units is placed.

The laser lift-off unit section 101 includes the position detection section 103, such as a camera or a position sensor, which recognizes a pattern of elements placed on a substrate and the contours of the element chips. The position matching section 106 checks inspection results of the position detection section 103 against those of the determination section 105 and identifies the location of an element chip to be removed. Next, the actuator 113 gets driven in accordance with an instruction from the control section 110, and the element chip to be removed from the substrate is irradiated with light falling on the opposite surface of the substrate. The light needs only be ultraviolet light or visible light. Further, the light source is selected from among light sources such as a laser, an LED, and a lamp. A combination with masking is conceivable depending on the size of the element chip to be removed and the bond between the element chip and the substrate.

In removing a light-emitting element chip on the sapphire substrate, which is a translucent substrate, as the substrate, a region in which a particular light-emitting element chip is located is selectively irradiated with light 71 at a wavelength of 20 to 400 nm in an ultraviolet range falling on the surface of the translucent substrate 11a (sapphire substrate) opposite to the surface on which the light-emitting element chips are placed. When the light-emitting element 31a is a gallium nitride element, irradiation with a pulse laser of nearly 250 nm causes gallium nitride nearly up to a level of several tens of nanometers from the translucent substrate 11a (sapphire substrate) to be decomposed into gallium and nitrogen, so that the light-emitting element 31a can be removed from the translucent substrate 11a (sapphire substrate). Accordingly, the element chip to be removed is selectively irradiated from the opposite surface of the substrate by relatively moving the substrate or the laser irradiation section from one position to another by driving the actuator. In view of the relationship between the size of an element chip and the spot diameter of a laser beam, it is advisable that in a case where the size of an element chip is smaller, positions other than the position to be irradiated be masked with a mask composed of a nontransparent material. In this case, the mask is moved from one position to another, too.

As for the removal of an element chip temporarily bonded in the loading step to the sapphire substrate, which is a translucent substrate, the glass substrate, which is a different translucent substrate, or the like as the substrate, a light source, a wavelength, an intensity, and the like are selected as appropriate according to the type of adhesive material. For example, transfer from the sapphire substrate, subjected to temporary bonding, to the mounting substrate can be done by using properties of the material such as photo-curability, thermal plasticity, water solubility, and vaporizability. Examples of photo-curable materials include visible light curing materials and ultraviolet curable materials. A generally well-known ultraviolet curable resin is cured with ultraviolet rays at a wavelength of 200 to 400 nm. Acrylic resin, which is generally well known, is widely used as an adhesive material for a dicing sheet, and is also used in a so-called UV sheet. The UV sheet includes a base material and a pressure-sensitive adhesive material applied to the base material, exhibits strong adhesiveness at the time of dicing when a wafer or a substrate is pasted and divided into individual pieces, and exhibits lower pressure-sensitive adhesiveness due to curing of the adhesive material by irradiation with ultraviolet rays before the small pieces are picked up after the division. This is how an ultraviolet curable resin is used. In recent years, there has been developed a resin that is cured with visible light (at a wavelength of approximately 400 to 800 nm). At 400 nm or longer, the material is characterized by having an increased light transmission. As adhesive materials, there are epoxy resin, polyimide resin, and the like in addition to acrylic resin. Using these materials makes it possible to perform temporary bonding to the sapphire substrate serving as the translucent substrate 11a and again remove the sapphire substrate serving as the translucent substrate 11a. In this case, it is advisable to shade parts other than the irradiation part with a mask and entirely irradiate the second surface of the substrate with an LED or a lamp. Since laser irradiation needs to involve a scan, a region that is wider than the second surface of the substrate can be favorably irradiated. The mask is moved by the actuator. In a case where there is a mixture of unreplaced element chips and replacement element chips on the sapphire substrate 11b, the element chips can be removed by the method for removing element chips, i.e. a combination of laser irradiation and isotropic irradiation. In a case where the removal of the unreplaced element chips needs much more energy of light than the removal of the replacement element chips, the mask does not need to be used for isotropic irradiation, which is simpler and more preferable.

Alternatively, there is a method for temporary bonding with a thermoplastic resin. A thermoplastic resin softens at or above a glass transition temperature or a melting point, and hardens at or below the temperature. Adhesion can be achieved by utilizing the properties of such a resin. This type of resin is used in a so-called hotmelt adhesive agent. There are a variety of materials examples of which include a polyimide material, a styrene-butadiene rubber material, and the like. Polyimide resin, which has a glass transition temperature of around 200° C. to 400° C., can achieve adhesion by being cooled after being once heated to 400° C. or higher at or above the glass transition temperature. Reheating to 400° C. or higher makes detachment possible. In this case, it is advisable to provide a substrate-fixing jig with heating means. For example, element chips of a rank other than the desired rank from among the element chips formed on the sapphire substrate are irradiated with light 71 at a wavelength of 20 to 400 nm. In the case of a light-emitting elements 31a that is a gallium nitride element, irradiation with a pulse laser of nearly 250 nm causes gallium nitride nearly up to a level of several tens of nanometers from the translucent substrate 11a (sapphire substrate) to be decomposed into gallium and nitrogen, so that the light-emitting element 31a can be removed from the translucent substrate 11a (sapphire substrate). An element chip of the desired rank is loaded by the temporary bonding into a place from which an element chip was removed. Next, in a case where the temporary bonding has been performed with a thermoplastic resin, gallium nitride is decomposed by a laser beam while being heated to 400° C. or higher by the heating means. In so doing, the laser irradiation may involve a scan of the entire substrate; however, as described with reference to FIG. 28, the scan is suspended at the position of an element chip to be removed from the substrate by the laser irradiation (i.e. the position of the laser irradiation section relative to the substrate), and is passed over the position of an element chip not to be removed by the laser irradiation (i.e. the position of the laser irradiation section relative to the substrate). This makes it possible to shorten machining time. Furthermore, it is preferable to combine the turning on of the laser irradiation at the position of the element chip to be removed by the laser irradiation and the turning off of the laser irradiation at the position of the element chip not to be removed by the laser irradiation, as doing so can make a great difference in state of bonding to an interface with the substrate between the element chip to be removed and the element chip not to be removed.

Temporary bonding involving the use of thermoplastic properties needs to be performed while heating in transferring to a different substrate or the mounting substrate. Therefore, it is advisable to provide the array device manufacturing repair apparatus 100 with the selective removal section 107. Further, there is an extreme reduction in bonding power to the interface with the substrate after laser irradiation of an unreplaced element chip on the substrate and there is therefore a risk of disengagement during handling, it is advisable to provide the array device manufacturing repair apparatus 100 with the selective removal section 107, although the element chip may be removed by a different apparatus.

In temporary bonding, examples of water-soluble materials include carbohydrate materials, protein materials, and the like usable examples of which include starch, collagen, gelatin, and the like. These materials need only be detached by moisture, and turning the moisture into hot water or vapor by heating makes detachment easy. In a case where there is a mixture of unreplaced element chips and such replacement element chips on the sapphire substrate, it is possible to remove the element chips through the concomitant use of selective removal by a laser beam and humidifying means or the like. Further, the water-soluble materials, such as carbohydrate materials and protein materials, most of which undergo change even at a not-so-high temperature, make it possible to easily remove replacement element chips. In this case, too, since there is a risk of disengagement during handling, it is advisable to provide the array device manufacturing repair apparatus 100 with the selective removal section 107.

Examples of organic materials include materials that can be detached by being decomposed, and instantaneously heating and vaporizing such a material with a pulse laser of ultraviolet light at a wavelength of 20 to 400 nm causes a phenomenon called “ablation” to take place. This phenomenon also takes place with the aforementioned gallium nitride. Even in a case where there is a mixture of unreplaced element chips and such replacement element chips on the sapphire substrate, the element chips can be removed by a laser beam method. Note, however, that it is advisable to change the wavelength, intensity, time, and the like of a laser beam according to the properties of a temporary bonding material. In this case, too, since there is a risk of disengagement during handling after laser irradiation, it is advisable to provide the array device manufacturing repair apparatus with the selective removal section 107. The selective removal section 107, which has been mentioned in the description so far, involves the use of any of the suction jigs 61, 62, and 63 and the substrate 11b, which have been described in relation to the method for manufacturing an array device. As for the substrate on which the element chips are provided, it is advisable to have a jig configured to hold the substrate by any three or more points on the periphery of the substrate or by the entire periphery around at least an element region of the substrate or a translucent jig and have a mechanism in which the jig moves. In a case where the substrate 11b is used, as for the substrate 11b, too, it is advisable to have a jig (that is different from the jig for the substrate) configured to hold the substrate by any three or more points on the periphery of the substrate or by the entire periphery around at least an element region of the substrate or a translucent jig (that is different from the jig for the substrate) and have a mechanism in which the jig moves.

It is preferable that the array device manufacturing repair apparatus 100 include a selective loading section 107. When the array device manufacturing repair apparatus 100 includes the selective loading section 107, the jig 61 for use in element chip removal can serve also as a suction jig for use in element chip loading so that the same operation of the apparatus 100 can be used to remove and load element chips. Further, when the array device manufacturing repair apparatus 100 includes the selective removal/loading section 107, the removal of element chips from the substrate 11a through the use of the substrate 11b and the transfer of element chips from the substrate 11b to the substrate 11c can both be achieved through the use of an operation in which the array device manufacturing repair apparatus 100 bonds substrates to each other, and the replacement of element chips on the substrate and the replacement of element chips on the mounting substrate can both be achieved through the use of the same operation of the array device manufacturing repair apparatus 100. Thus, although these operations or processes may be performed separately by different apparatus, different units of one apparatus, or the like, FIG. 29 describes a combination of a selective removal section and a selective loading section as “selective removal(/loading) section 107”, as these operations or processes can be performed by one apparatus.

Further, although the description has been given so far to the effect that an inspection result is obtained from a different apparatus, the array device manufacturing repair apparatus 100 may further include an inspection section 108 that inspects a plurality of elements. That is, the array device manufacturing repair apparatus 100 may inspect a plurality of elements. A reason for this is that doing so makes it conceivable that an inspection result 2 obtained by the array device manufacturing repair apparatus 100 may be sent to the storage section of 104 of the array device manufacturing repair apparatus 100, or directly to the determination section 105. The inspection section 108 may carry out an inspection by a probing method, or may carry out an inspection by a non-contact method. Inspections carried out by the manufacturing methods and the manufacturing apparatuses according to the present invention include probing or non-contact inspections. The term “probing” encompasses probing that is performed by bringing an element and the mounting substrate or an LSI substrate serving as the mounting substrate 21 into contact with each other via a bump and passing a current through them. A reason for this is that providing the inspection section 108 makes it possible to avoid human errors such as swapping of inspection results with another substrate.

The use of the array device manufacturing repair apparatus 100 makes it possible to achieve higher definition (in the case of display devices) and smaller sizes, which bring advantages to array devices, and achieve manufactures at overwhelmingly higher mounting speeds than the pick-and-place scheme, and furthermore, in the manufacture of array devices, the array device manufacturing repair apparatus 100 can be used in the element chip replacing step (removing step, loading step), the post-mounting element chip replacing step (post-mounting removing step, remounting step), and the substrate removing step to manufacture high yields of high-quality array devices in a simple way.

The array device manufacturing repair apparatus 100, which has been described so far, is not limited to selective irradiation or selective removal with light, but utilizing the mechanism for bonding substrates to each other makes pasting and transfer between substrates and pasting and transfer between a substrate and a mounting substrate possible. Further, it can be utilized for pasting, transfer, mounting, and the like without being limited to array devices.

A description is given below with reference to flow charts that describe the method for manufacturing an array device.

For example, the processes described in steps S102, S202, S302, S402, S512, S612, and S712, which have been described in relation to the aforementioned manufacturing steps, include placing elements by forming the elements on a substrate in step S102, S5202, S302, or S402 and placing elements by transfer in step S512, S5612, or S712. Note, however, that providing the array device manufacturing repair apparatus 100 with the loading section 107 makes it possible to also use the array device manufacturing repair apparatus 100 in step S512, S5612, or S712 (although there is a need for heating means, depending on the bonding method). That is, providing the loading section 107 makes it possible to use the array device manufacturing repair apparatus 100 in step S512, S612, or S712 to place elements and selectively irradiate them with light. Providing the array device manufacturing repair apparatus 100 with the loading section 107 makes it possible to also use the array device manufacturing repair apparatus 100 as a transfer apparatus in step S508, S5608, or S5708.

Next, the processes described in steps S104, S204, S5304, S404, S504, S604, and S704, which have been described in relation to the aforementioned manufacturing steps, include separating the elements so that one or a plurality of the elements are included. Note, however, that the placing step of providing a plurality of elements in an array on a first surface of a substrate is executed in the aforementioned step S512, S612, or S712 and is therefore preceded by the element separating step. A reason for this is that transfer is easier done after element separation. Note, however, that if transfer is possible even before element separation, element separation may be executed after step S512, S612, or S5712. That is, the placing step and the element separating step may be executed in any order. Furthermore, the inspecting step, which is a process described above in step S106, S206, S306, S5406, S506, S5606, or S706 in relation to the aforementioned manufacturing steps, is executed. Note, however, that the inspecting step may be executed after the step of providing elements or after the element separating step. Further, the inspecting step can be executed by providing the array device manufacturing repair apparatus 100 with the inspection section 108.

After that, an inspection result (including positional information) yielded in the inspecting step is stored in the storage section 104 (or may be sent directly to the determination section 105), and an element chip to be removed is selected by the determination section 105 according to specifications and rank information. The positional information of the element chip as obtained by the position detection section is checked against the inspection result including positional information. As described previously, the element chip is selectively irradiated with light so that the bond of the element chip to the substrate can be weakened. After that, the element chip may be removed by a different apparatus through the use of the suction jig 61, 62, or 63, the substrate 11b, or the like.

By further including the selective removal/loading section 107 for removing and loading element chips, the array device manufacturing repair apparatus 100 can go as far as to remove element chips instead of the different apparatus. That is, having a mechanism for removing element chips with the suction jig 61, 62, or 63 makes it possible to complete the removing step in a sequential fashion upon or slightly after weakening the bond. The substrate 11b or 11c may be used instead of the suction jig as a selective removal mechanism. This brings the advantages described in relation to the aforementioned manufacturing method. That is, the use of the substrate 11b or 11c makes it possible to remove element chips over a wide range. Further, the use of a translucent substrate as the substrate 11b or 11c makes selective irradiation possible also from the substrate 11b or 11c side, making it easy to establish the relational expressions described in relation to the aforementioned manufacturing method.

It is advisable for the selective removal/loading section 107 to be able to further perform loading. That is, a mechanism configured to load a desired element chip into a place on the substrate 11a from which an element chip was removed makes it possible to complete the whole replacing step in a sequential fashion through the removing step and the loading step on the substrate, thus making it possible to further simplify the replacing step. For mass production, a plurality of the array device manufacturing repair apparatuses may be prepared and play their respective roles in the removing step and the loading step.

As the selective removing step described in relation to the aforementioned manufacturing steps, the process described in step S108, S110, S208, S210, S308, S310, S408, S410, S512, S514, S612, S614, S712, or S714 can be executed.

Furthermore, the loading section 107 executes, as the loading step described in relation to the aforementioned manufacturing steps, the process described in step S112, S216, S312, S416, S516, S618, S716, S806, or S906, which have been described in relation to the aforementioned manufacturing steps.

Further, the array device manufacturing repair apparatus 100 can also be applied to the removing step after element chip mounting and the remounting step. First, a different apparatus can carry out a post-mounting inspection in step S800 or S900 and, on the basis of an inspection result 1 (including positional information) obtained therefrom, perform selective irradiation in step S802 or S902. In this case, it is advisable to peel the substrate from the mounting substrate by, without weakening the bonding power of defective element chips to the substrate, weakening the bonding power of conforming element chips to the substrate by selectively irradiating the conforming element chips from the substrate side. Providing the array device manufacturing repair apparatus 100 with the selective removal(/loading) section 107 makes it also possible to execute the post-mounting selective removal and the remounting step S806 or S906. Further, providing the array device manufacturing repair apparatus 100 with the inspection section 108 makes it possible to use a post-mounting inspection result 2 (including positional information) instead of the different apparatus.

The array device manufacturing repair apparatus (apparatus for manufacturing an array device) makes it possible to appropriately and easily remove an element chip of a quality other than the desired quality (such as one that fails to light) and then replace it with an element chip of the desired quality, thus making it possible to provide an apparatus configured to manufacture high yields of array devices.

### REFERENCE SIGNS LIST

100 Array device manufacturing repair apparatus (apparatus for manufacturing array device)

101 Laser lift-off unit section

102 Selective irradiation section

103 Position detection section

104 Storage section

105 Determination section

106 Position matching section

108 Inspection section

107 Selective removal(/loading) section

110 Control section

113, 114 Actuator

201, 202 Array device (display device)

11, 11a, 11b, 11c (Translucent) substrate

12 Silicon substrate

21 Mounting substrate

31 Light-emitting element chip

31a Light-emitting element

31b Light-emitting-element-free region

32, 33 Defective light-emitting element chip

41 Bump

51 Resin material

61, 62, 63 Suction jig

81 Display device region

82 Region other than display device region 81

1. A method for manufacturing an array device, the method comprising:
a placing step of providing a plurality of elements in an array on a first surface of a substrate;
an element separating step of separating a plurality of element chips from one another so that each element chip includes one or more elements;
an inspecting step of inspecting the plurality of elements;
a removing step of removing any element chip of the plurality of element chips from the surface of the substrate on the basis of a result of the inspecting step; and
a mounting step of, after the removing step, mounting an element of at least the elements other than an element of the element chip thus removed onto a mounting substrate by transfer from the substrate, the mounting substrate being different from the substrate.

2 the method according to claim 1, further comprising a loading step of, after the removing step, loading an element chip of a desired quality onto the substrate on the basis of the result of the inspecting step.

3. the method according to claim 1, wherein the mounting step includes mounting each element chip onto the mounting substrate while maintaining relative coordinates of the plurality of elements.

4. The method according to claim 1, wherein the elements are light-emitting elements.

5. The method according to claim 1, wherein the mounting substrate is an LSI substrate.

6. The method according to claim 1, wherein the substrate is a translucent substrate that transmits light.

7. The method according to claim 6, wherein the removing step includes weakening bonding power between an element chip and the translucent substrate by selectively irradiating the element chip with light falling on a surface of the translucent substrate opposite to the surface on which the elements are provided.

8. The method according to claim 1, wherein the mounting step includes performing mounting with reference to a determination result as to whether electrical continuity has been achieved by bringing electrodes of the element chips and electrodes of the mounting substrate into contact with each other.

9. The method according to claim 1, further comprising a post-mounting inspecting step of, after the mounting step, determining whether an element chip that has been mounted is defective.

10. The method according to claim 9, further comprising:
a post-mounting removing step of removing, with reference to an inspection result yielded in the post-mounting inspecting step, a defective element chip that has been mounted; and
a remounting step of, after the post-mounting removing step, mounting an element chip of a desired quality onto the mounting substrate with a paste material containing conductive particles.

11. The method according to claim 1, further comprising a substrate removing step of removing the substrate after the mounting step.

12. The method according to claim 11, wherein the substrate removing step after the mounting step includes removing the substrate and selectively removing a defective element chip on the basis of a result of a post-mounting inspecting step.

13. The method according to claim 2, wherein
the removing step includes removing a defective element chip from the substrate by attaching the defective element chip to a second substrate that is different from the substrate, and
the loading step includes
an attaching step of further attaching an element chip of a desired quality onto the defective element chip attached to the second substrate, and
a transferring step of transferring the element chip of the desired quality attached to the second substrate onto the substrate on the basis of positional information of the defective element chip removed from the substrate and thereby replacing the defective element chip thus removed with the element chip of the desired quality.

14. The method according to claim 10, wherein the remounting step includes
an attaching step of attaching an element chip of a desired quality onto a defective element chip removed from the mounting substrate by using the substrate or a third substrate that is different from the substrate, and
a transferring step of transferring the element chip of the desired quality attached to the substrate or the third substrate onto the mounting substrate on the basis of positional information of the defective element chip removed from the mounting substrate and thereby replacing the defective element chip thus removed with the element chip of the desired quality.

15. An apparatus for manufacturing an array device, the apparatus comprising:
a determination section that determines, on the basis of an inspection result of each element, whether an element chip separated so as to include one or a plurality elements is removed; and
a selective irradiation section that, on the basis of a determination result yielded by the determination section, selectively irradiates the element chip with light falling on a second surface of a translucent substrate opposite to a first surface of the translucent substrate on which the element chip is placed.

16. The apparatus according to claim 15, further comprising a selective removal section that removes a particular element chip from the translucent substrate.

17. The apparatus according to claim 15, further comprising an inspection section that inspects the plurality of elements.

18. The apparatus according to claim 15, further comprising a loading section that loads a different element chip in a place on the translucent substrate from which the element chip was removed.
